(19) United States
(12) Patent Application Publication
(10) Pub. No.: US 2024/0196617 A1
(43) Pub. Date: Jun. 13, 2024

(54) SEMICONDUCTOR DEVICE AND ELECTRONIC SYSTEM COMPRISING THE SAME

(71) Applicant: Samsung Electronics Co., Ltd., Suwon-si (KR)

(72) Inventors: Seungmin Lee, Suwon-si (KR); Jihwan Yu, Suwon-si (KR); Byungman Ahn, Suwon-si (KR); Bonghyun Choi, Suwon-si (KR)

(21) Appl. No.: 18/511,396

(22) Filed: Nov. 16, 2023

(30) Foreign Application Priority Data
Dec. 7, 2022 (KR) 10-2022-0170048

(51) Int. Cl. H10B 43/27; G11C 16/04; H01L 25/065; H10B 41/10; H10B 41/27; H10B 41/35; H10B 43/10; H10B 43/35; H10B 80/00

(52) U.S. Cl. CPC H10B 43/27; G11C 16/0483; H01L 25/0652; H10B 41/10; H10B 41/27; H10B 41/35; H10B 43/10; H10B 43/35; H10B 80/00; H01L 2225/06506

(57) ABSTRACT

A semiconductor device includes a substrate comprising a chip region and a scribe lane region including a first key pattern region, a capping insulating layer disposed on the scribe lane region, a barrier metal layer covering the capping insulating layer and an inner wall of a via hole penetrating the capping insulating layer, a substrate layer disposed on the barrier metal layer and filling the via hole, an insulating plate and an upper base layer disposed on the substrate layer, a pattern insulating layer disposed on the capping insulating layer in the first key pattern region, a stacked structure disposed on the upper base layer and the pattern insulating layer, and first pattern structures overlapping the pattern insulating layer in a vertical direction and penetrating the stacked structure and the pattern insulating layer, wherein the pattern insulating layer extends through the barrier metal layer in the first key pattern region.

### CROSS-REFERENCE TO RELATED APPLICATION

This application is based on and claims priority under 35 U.S.C. § 119 to Korean Patent Application No. 10-2022-0170048, filed on Dec. 7, 2022, in the Korean Intellectual Property Office, the disclosure of which is incorporated by reference herein in its entirety.

### BACKGROUND

The inventive concept relates to a semiconductor device and an electronic system including the semiconductor device. Specifically, the inventive concept relates to a semiconductor device including a non-volatile vertical memory device and an electronic system including the semiconductor device.

In an electronic system requiring data storage, a semiconductor device capable have high-capacity data storage capabilities is required, and accordingly, a method of increasing the data storage capacity of the semiconductor device has been researched. For example, as one of the methods of increasing the data storage capacity of the semiconductor device, a semiconductor device including a vertical memory device having three-dimensionally arranged memory cells instead of two-dimensionally arranged memory cells is proposed.

### SUMMARY

The inventive concept provides a semiconductor device having improved structural reliability and performance while preventing contamination of semiconductor equipment used to manufacture the semiconductor device, and an electronic system including the semiconductor device.

According to an aspect of the inventive concept, there is provided a semiconductor device including a substrate including a chip region and a scribe lane region around the chip region and including a first key pattern region, a capping insulating layer disposed on the scribe lane region, a barrier metal layer covering the capping insulating layer and an inner wall of a via hole penetrating the capping insulating layer, a substrate layer disposed on the barrier metal layer and filling the via hole, an insulating plate and an upper base layer sequentially disposed on the substrate layer, a pattern insulating layer disposed on the capping insulating layer in the first key pattern region, a stacked structure disposed on the upper base layer and the pattern insulating layer, and a plurality of first pattern structures overlapping the pattern insulating layer in a vertical direction and penetrating the stacked structure and a part of the pattern insulating layer, wherein the pattern insulating layer extends through the barrier metal layer in the first key pattern region in a vertical direction.

According to another aspect of the inventive concept, there is provided a semiconductor device including a substrate including a chip region including a memory cell region and a connection region, a capping insulating layer disposed on the chip region, a barrier metal layer covering the capping insulating layer and an inner wall of a via hole penetrating the capping insulating layer, a substrate layer disposed on the barrier metal layer and filling the via hole, a lower base layer disposed on the substrate layer in the memory cell region and an insulating plate disposed on the substrate layer in the connection region, an upper base layer disposed on the lower base layer and the insulating plate, a pattern insulating layer disposed on the capping insulating layer in a partial region of the connection region, a stacked structure disposed on the pattern insulating layer and the upper base layer, and a plurality of dummy channel structures overlapping the pattern insulating layer in a vertical direction and penetrating the stacked structure and a part of the pattern insulating layer, wherein the pattern insulating layer extends through the barrier metal layer in the connection region in a vertical direction.

According to another aspect of the inventive concept, there is provided an electronic system including a main substrate, a semiconductor device on the main substrate, and a controller electrically connected to the semiconductor device on the main substrate, wherein the semiconductor device includes a substrate including a chip region and a scribe lane region around the chip region and including a first key pattern region, a capping insulating layer disposed on the scribe lane region, a barrier metal layer covering the capping insulating layer and an inner wall of a via hole penetrating the capping insulating layer, a substrate layer disposed on the barrier metal layer and filling the via hole, an insulating plate and an upper base layer sequentially disposed on the substrate layer, a pattern insulating layer disposed on the capping insulating layer in the first key pattern region, a stacked structure disposed on the upper base layer and the pattern insulating layer, and a plurality of first pattern structures overlapping the pattern insulating layer in a vertical direction and penetrating the stacked structure and a part of the pattern insulating layer, wherein the pattern insulating layer extends through the barrier metal layer in the first key pattern region in a vertical direction.

### BRIEF DESCRIPTION OF THE DRAWINGS

Embodiments will be more clearly understood from the following detailed description taken in conjunction with the accompanying drawings in which:

FIG. 1 is a block diagram of a semiconductor device, according to an example embodiment;

FIG. 2 is an equivalent circuit diagram of a memory cell array of a semiconductor device according to an example embodiment;

FIG. 3 is a plan view illustrating a part of a semiconductor device, according to an example embodiment;

FIG. 4 is a cross-sectional view illustrating a chip region of a semiconductor device, according to an example embodiment;

FIG. 5A is a plan view illustrating a first key pattern region of a semiconductor device, according to an example embodiment;

FIG. 5B is a cross-sectional view taken along a line A-A′ of FIG. 5A;

FIG. 6A is a plan view illustrating a second key pattern region of a semiconductor device, according to an example embodiment;

FIG. 6B is a cross-sectional view taken along a line B-B′ of FIG. 6A;

FIG. 7 is a cross-sectional view of a semiconductor device, according to an example embodiment;

FIG. 8 is a cross-sectional view of a part of a chip region of a semiconductor device, according to an example embodiment;

FIGS. 9A to 10D are cross-sectional views illustrating a method of manufacturing a semiconductor device, according to an example embodiment;

FIG. 11 is a diagram schematically illustrating an electronic system including a semiconductor device, according to an example embodiment;

FIG. 12 is a perspective view schematically illustrating an electronic system including a semiconductor device, according to an example embodiment; and

FIG. 13 is a cross-sectional view schematically illustrating semiconductor packages, according to an example embodiment.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof may not be repeated.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

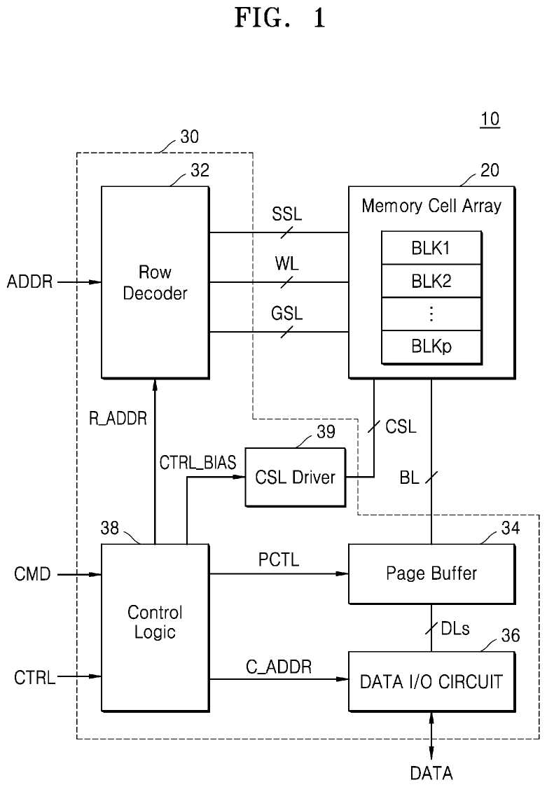

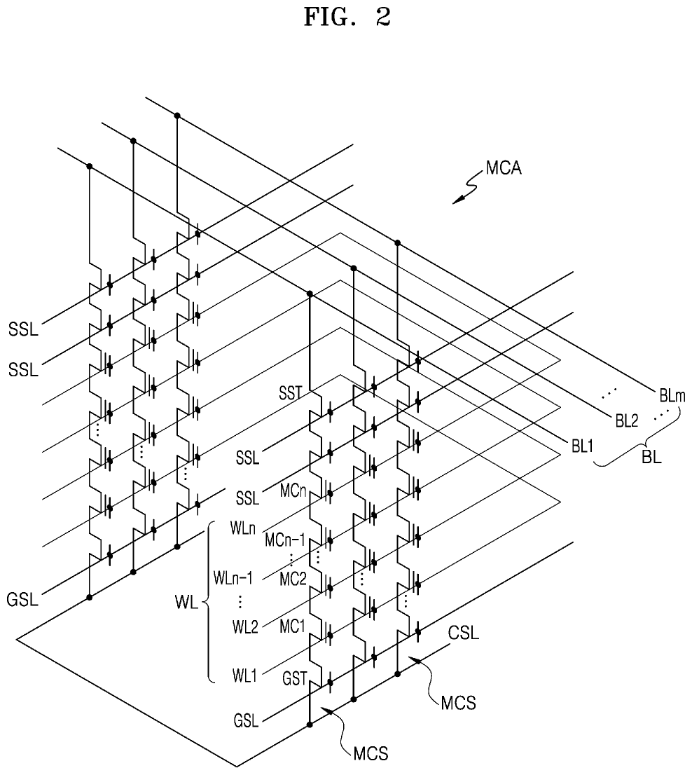

FIG. 1 is a block diagram of a semiconductor device 10 according to an example embodiment.

Referring to FIG. 1, the semiconductor device 10 may include a memory cell array 20 and a peripheral circuit 30. The memory cell array 20 includes a plurality of memory cell blocks BLK1, BLK2, . . . , BLKp. Each of the plurality of memory cell blocks BLK1, BLK2, . . . , BLKp may include a plurality of memory cells. The memory cell blocks BLK1, BLK2, . . . , BLKp may be connected to the peripheral circuit 30 through bit lines BL, word lines WL, a string selection line SSL, and a ground selection line GSL.

The peripheral circuit 30 may include a row decoder 32, a page buffer 34, a data input/output (I/O) circuit 36, control logic 38, and a common source line (CSL) driver 39. Although not illustrated, the peripheral circuit 30 may further include various circuits, such as a voltage generation circuit generating various voltages necessary for the operation of the semiconductor device 10, an error correction circuit for correcting errors in data read from the memory cell array 20, an input/output interface, etc.

The memory cell array 20 may be connected to the row decoder 32 through the word lines WL, the string selection lines SSL, and the ground selection lines GSL, and to the page buffer 34 through the bit lines BL. In the memory cell array 20, each of the plurality of memory cells included in the plurality of memory cell blocks BLK1, BLK2, . . . , BLKp may be a flash memory cell. The memory cell array 20 may include a 3D memory cell array. The 3D memory cell array may include a plurality of NAND strings, and each of the plurality of NAND strings may include a plurality of memory cells respectively connected to a plurality of vertically stacked word lines WL.

The peripheral circuit 30 may receive an address ADDR, a command CMD, and a control signal CTRL from the outside of the semiconductor device 10, and may transmit/receive data DATA to/from a device outside the semiconductor device 10.

The row decoder 32 may select at least one of the plurality of memory cell blocks BLK1, BLK2, . . . , BLKp in response to the address ADDR from the outside, and may select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array 20 through the bit lines BL. The page buffer 34 may operate as a write driver during a program operation to apply a voltage according to the data DATA to be stored in the memory cell array 20 to the bit line BL, and may operate as a sense amplifier during a read operation to sense the data DATA stored in the memory cell array 20. The page buffer 34 may operate according to a control signal PCTL provided from the control logic 38.

The data input/output circuit 36 may be connected to the page buffer 34 through a plurality of data lines DLs. The data input/output circuit 36 may receive the data DATA from a memory controller (not shown) during a program operation, and provide the program data DATA to the page buffer 34 based on a column address C_ADDR provided from the control logic 38. During a read operation, the data input/output circuit 36 may provide the read data DATA stored in the page buffer 34 to the memory controller based on the column address C_ADDR provided from the control logic 38.

The data input/output circuit 36 may transfer an input address or command to the control logic 38 or the row decoder 32. The peripheral circuit 30 may further include an electro static discharge (ESD) circuit and a pull-up/pull-down driver.

The control logic 38 may receive the command CMD and the control signal CTRL from the memory controller. The control logic 38 may provide the row address R_ADDR to the row decoder 32 and the column address C_ADDR to the data input/output circuit 36. The control logic 38 may generate various internal control signals used in the semiconductor device 10 in response to the control signal CTRL. For example, the control logic 38 may adjust voltage levels provided to the word line WL and the bit line BL when performing a memory operation, such as a program operation or an erase operation.

The common source line driver 39 may be connected to the memory cell array 20 through the common source line CSL. The common source line driver 39 may apply a common source voltage (e.g., a power supply voltage) or a ground voltage to the common source line CSL based on a control signal CTRL_BIAS of the control logic 38.

FIG. 2 is an equivalent circuit diagram of a memory cell array MCA of the semiconductor device 10 according to example embodiments.

Referring to FIG. 2, the memory cell array MCA may include a plurality of memory cell strings MCS. The memory cell array MCA may include a plurality of bit lines BL (e.g., BL1, BL2, . . . , BLm), a plurality of word lines WL (e.g., WL1, WL2, . . . , WLn−1, WLn), at least one string selection line SSL, at least one ground selection line GSL, and the common source line CSL. The plurality of memory cell strings MCS may be formed between the plurality of bit lines BL and the common source line CSL. Although FIG. 2 illustrates a case where each of the plurality of memory cell strings MCS includes two string selection lines SSL, the inventive concept is not limited thereto. For example, each of the plurality of memory cell strings MCS may include one string selection line SSL.

Each of the plurality of memory cell strings MCS may include a string selection transistor SST, a ground selection transistor GST, and a plurality of memory cell transistors MC1, MC2, . . . , MCn−1, MCn. A drain region of the string selection transistor SST may be connected to a corresponding one of the bit lines BL, and a source region of the ground selection transistor GST may be connected to the common source line CSL. The common source line CSL may be a region where source regions of the plurality of ground selection transistors GST are connected in common.

The string selection transistor SST may be connected to the string selection line SSL, and the ground selection transistor GST may be connected to the ground selection line GSL. The plurality of memory cell transistors MC1, MC2, . . . , MCn−1, MCn may be connected to the plurality of word lines WL, respectively.

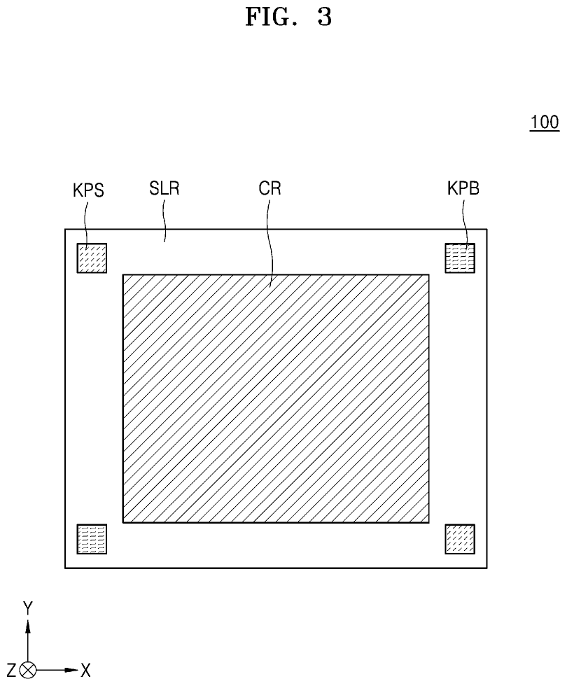

FIG. 3 is a plan view illustrating a partial region of a semiconductor device 100 according to an example embodiment.

Referring to FIG. 3, the semiconductor device 100 may include a chip region CR and a scribe lane region SLR surrounding the chip region CR. The chip region CR may be a high-density region having a relatively high pattern density, and the scribe lane region SLR may be a low-density region having a relatively low pattern density. The chip region CR may include a cell array region of a semiconductor memory device, a peripheral circuit region including circuits configured to be electrically connected to cell arrays included in the cell array region, and a core region. In some embodiments, the chip region CR may include at least one non-volatile memory device. In some embodiments, the at least one non-volatile memory device may include a NAND flash memory, a vertical NAND memory (hereinafter referred to as ‘VNAND’), a NOR flash memory, Resistive Random Access Memory (RRAM), Phase-Change Memory (PRAM), Magnetoresistive Random Access Memory (MRAM), Ferroelectric Random Access Memory (FRAM), Spin Injection Spin Transfer Torque Random Access Memory (STT-RAM), or a combination thereof. The at least one non-volatile memory device may be implemented as a three-dimensional (3D) array structure. For example, the chip region CR may include the memory cell array 20 and the peripheral circuit 30 included in the semiconductor device 10 described with reference to FIG. 1. In some embodiments, the at least one non-volatile memory device may further include a volatile memory device such as dynamic random access memory (DRAM).

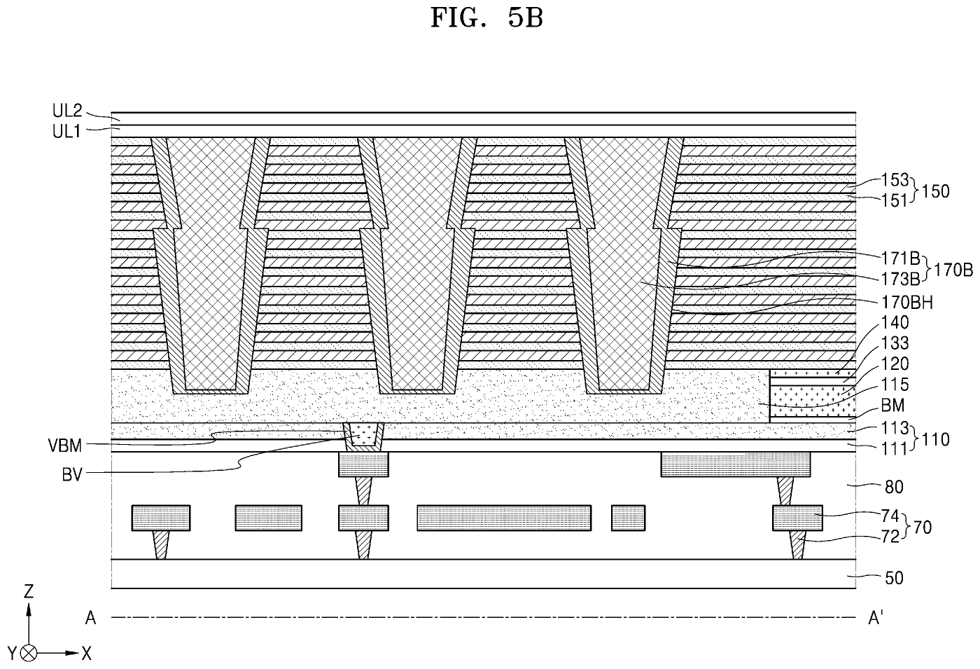

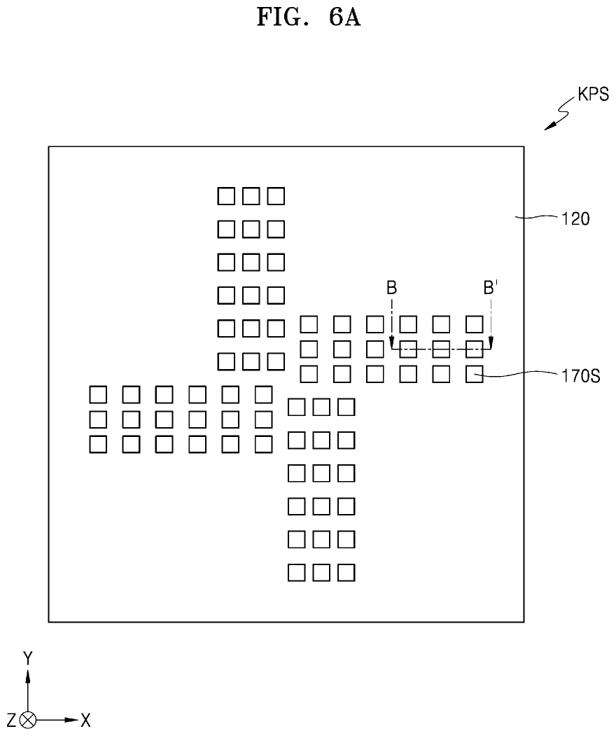

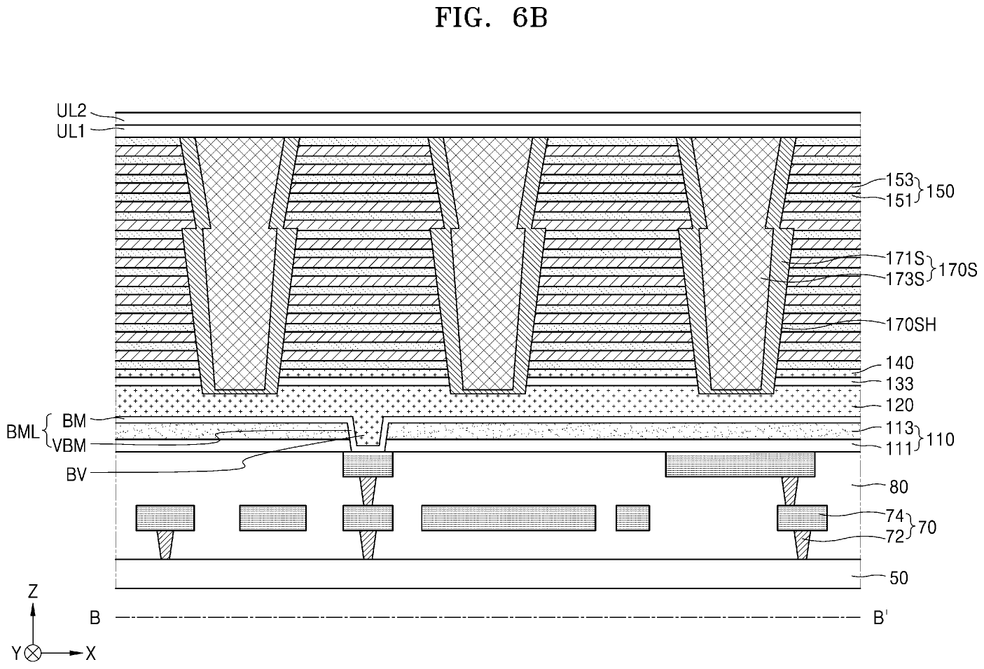

The scribe lane region SLR is a part of the scribe lane region of a wafer (not shown) which remains around the chip region CR after the individualization process of the chip region CR. In an embodiment, the scribe lane region SLR may include a first key pattern region KPB and a second key pattern region KPS. On the scribe lane region SLR, the first key pattern region KPB and the second key pattern region KPS may be arranged around the edge corners of the chip region CR. For example, on the scribe lane region SLR, the first key pattern region KPB may be disposed outside both vertices of the chip region CR facing each other in an oblique direction, and the second key pattern region KPS may be disposed outside the other both vertices of the chip region CR. However, the inventive concept is not limited thereto, and the first key pattern region KPB and the second key pattern region KPS may be arranged in other ways as desired. Various keys, such as an alignment key, an overlay key, and a focus key, may be disposed in the first key pattern region KPB and the second key pattern region KPS. In addition, the same type of keys or different types of keys may be arranged in the first key pattern region KPB and the second key pattern region KPS. The first key pattern region KPB and the second key pattern region KPS are described below in detail with reference to FIGS. 5A to 6B.

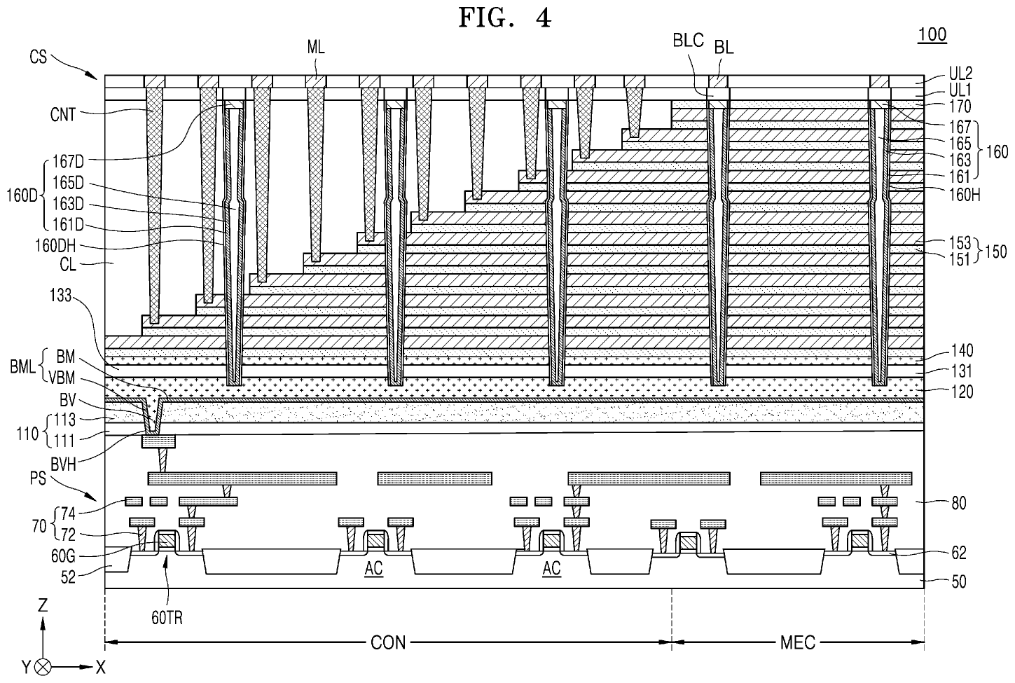

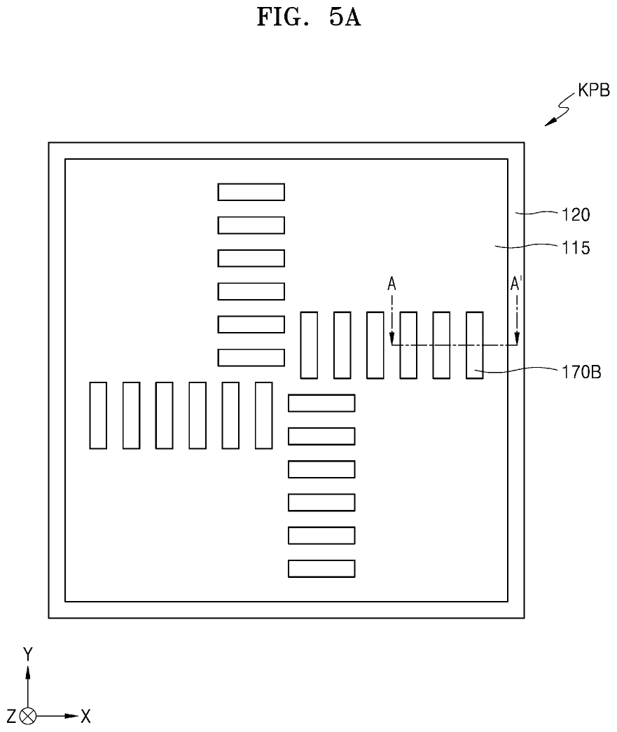

FIG. 4 is a cross-sectional view of a semiconductor device 100 according to an example embodiment. Specifically, FIG. 4 is a cross-sectional view illustrating a part of the chip region (e.g., chip region CR of FIG. 3) of the semiconductor device 100.

Referring to FIG. 4, the semiconductor device 100 may include a cell array structure CS and a peripheral circuit structure PS overlapping each other in a vertical direction (Z direction).

The cell array structure CS may include a memory cell region MEC in which the memory cell array 20 described with reference to FIG. 1 is disposed and a connection region CON disposed on one side of the memory cell region MEC in a first horizontal direction (X direction).

The peripheral circuit structure PS may include a substrate 50, peripheral circuit transistors 60TR disposed on the substrate 50, and a peripheral circuit wiring structure 70. The first horizontal direction (X direction) and a second horizontal direction (Y direction) may be directions that are parallel to an upper surface of the substrate 50 and perpendicular to one another. The vertical direction (Z direction) may be a direction that is perpendicular to the upper surface of the substrate 50.

The substrate 50 may be a semiconductor substrate. For example, the substrate 50 may include Si, Ge, or SiGe. An active region AC may be defined by a device isolation layer 52 in the substrate 50, and the plurality of peripheral circuit transistors 60TR may be formed on the active region AC. The plurality of peripheral circuit transistors 60TR may include a peripheral circuit gate 60G and source/drain regions 62 disposed on parts of the substrate 50 of both sides of the peripheral circuit gate 60G. The plurality of peripheral circuit transistors 60TR may comprise the peripheral circuit 30 described with reference to FIG. 1.

A plurality of peripheral circuit wiring structures 70 may include a plurality of peripheral circuit contacts 72 and a plurality of peripheral circuit wiring layers 74. At least some of the plurality of peripheral circuit wiring layers 74 may be configured to be electrically connectable to the peripheral circuit transistor 60TR. The plurality of peripheral circuit contacts 72 may be configured to interconnect some selected from among the plurality of peripheral circuit transistors 60TR to the plurality of peripheral circuit wiring layers 74. The plurality of peripheral circuit transistors 60TR and the plurality of peripheral circuit wiring structures 70 included in the peripheral circuit structure PS may be covered by an interlayer insulating layer 80. The interlayer insulating layer 80 may include a silicon oxide layer, a silicon nitride layer, a SiON layer, a SiOCN layer, or a combination thereof.

A capping insulating layer 110 may be disposed on the interlayer insulating layer 80. The capping insulating layer 110 may include a first capping insulating layer 111 and a second capping insulating layer 113 sequentially disposed on the interlayer insulating layer 80. The first capping insulating layer 111 may include, for example, silicon nitride, and the second capping insulating layer 113 may include, for example, silicon oxide.

The capping insulating layer 110 may have a via hole BVH. The via hole BVH may extend through the capping insulating layer 110 in a vertical direction (Z direction). Specifically, the via hole BVH may extend from the upper surface of the second capping insulating layer 113 to the lower surface of the first capping insulating layer 111. A part of the peripheral circuit wiring layer 74 may be exposed by the via hole BVH.

A barrier metal layer BML may cover the upper surface of the capping insulating layer 110 and the inner wall of the via hole BVH. In an embodiment, the barrier metal layer BML may conformally cover the upper surface of the capping insulating layer 110 and the inner wall of the via hole BVH. For example, the barrier metal layer BML may contact the upper surface of the capping insulating layer 110 and the inner wall of the via hole BVH. The barrier metal layer BML may include a first barrier metal layer BM covering the upper surface of the capping insulating layer 110 and a second barrier metal layer VBM covering the inner wall of the via hole BVH. In an embodiment, the first barrier metal layer BM and the second barrier metal layer VBM may include a metal nitride or a metal silicide. For example, the first barrier metal layer BM and the second barrier metal layer VBM may include TIN, Ti—Si—N(TSN), WN, or WSi. The first barrier metal layer BM and the second barrier metal layer VBM are named for convenience of explanation, and may be formed together. Accordingly, the first barrier metal layer BM and the second barrier metal layer VBM may be integrated.

A substrate layer 120 may be disposed on the barrier metal layer BML. The substrate layer 120 may contact an upper surface of the barrier metal layer BML. The substrate layer 120 may function as a source region supplying current to vertical memory cells formed in the cell array structure CS. In an embodiment, the substrate layer 120 may include a semiconductor material, such as polysilicon. A part of the substrate layer 120 may form a via BV by filling an empty space inside the second barrier metal layer VBM covering the inner wall of the via hole BVH. For example, the substrate layer 120 may be formed together with the via BV, and may be integrated. The peripheral circuit wiring structure 70 and the substrate layer 120 may be electrically connected to each other through the via BV.

A lower base layer 131 may be disposed on the substrate layer 120 in the memory cell region MEC. The lower base layer 131 may contact the substrate layer 120. The lower base layer 131 may include, for example, polysilicon doped with impurities, polysilicon undoped with impurities, metal, or a combination thereof. The lower base layer 131 may function as a source region supplying current to vertical memory cells formed in the cell array structure CS together with the substrate layer 120.

An insulating plate 133 may be disposed on the substrate layer 120 in the connection region CON. The insulating plate 133 may contact the substrate layer 120. In an embodiment, the insulating plate 133 may be an insulating material layer having an Oxide-Nitride-Oxide (ONO) structure. For example, the insulating plate 133 may include a plurality of insulating layers sequentially stacked on the substrate layer 120.

An upper base layer 140 may be disposed on the lower base layer 131 and the insulating plate 133. The upper base layer 140 may contact the lower base layer 131 and the insulating plate 133. The upper base layer 140 may include a semiconductor material. For example, the upper base layer 140 may include polysilicon doped with impurities, polysilicon undoped with impurities, metal, or a combination thereof. The upper base layer 140 may function as a source region supplying current to vertical memory cells formed in the cell array structure CS together with the substrate layer 120 and the lower base layer 131.

A stacked structure 150 may be disposed on the upper base layer 140. The stacked structure 150 may include a plurality of insulating layers 151 and a plurality of gate electrodes 153 alternately disposed in a vertical direction (Z direction). The plurality of insulating layers 151 may include, for example, silicon oxide, silicon nitride, or silicon oxynitride. The plurality of gate electrodes 153 may include, for example, tungsten, nickel, cobalt, tantalum, tungsten nitride, titanium nitride, tantalum nitride, or a combination thereof. The plurality of gate electrodes 153 may correspond to the ground selection line GSL, the word lines WL, and at least one string selection line SSL constituting the memory cell string MCS (see FIG. 2). For example, in FIG. 4, the uppermost gate electrode 153 may function as the ground selection line GSL, the lowermost two gate electrodes 153 in FIG. 4 may function as the string selection lines SSL, and the remaining gate electrodes 153 may function as the word lines WL.

The stacked structure 150 may extend to have a length decreasing in the first horizontal direction (X direction) away from the substrate layer 120 on the connection region CON. That is, the stacked structure 150 may have a stepped structure.

The stacked structure 150 may be covered by an interlayer insulating layer CL. The interlayer insulating layer CL may contact upper and side surfaces of the plurality of insulating layers 151 and the plurality of gate electrodes 153. The interlayer insulating layer CL may include a silicon oxide layer, a silicon nitride layer, or a combination thereof.

A plurality of channel structures 160 may be disposed in the memory cell region MEC. Each of the plurality of channel structures 160 may penetrate the stacked structure 150, the upper base layer 140, the lower base layer 131, and at least a part of the substrate layer 120 and extend in the vertical direction (Z direction). Accordingly, lower surfaces of the plurality of channel structures 160 may be in contact with the substrate layer 120. For example, lower surfaces of the plurality of channel structures 160 may be at a lower vertical level than an upper surface of the substrate layer 120. The plurality of channel structures 160 may be arranged to be spaced apart from each other with a certain space therebetween in the first horizontal direction (X direction) and the second horizontal direction (Y direction).

Each of the plurality of channel structures 160 may include a gate insulating layer 161, a channel layer 163, a filling insulating layer 165, and a conductive plug 167. The gate insulating layer 161 and the channel layer 163 may be sequentially disposed on the sidewall of a channel hole 160H. For example, the gate insulating layer 161 may be conformally disposed on the sidewall of the channel hole 160H, and the channel layer 163 may be conformally disposed on the sidewall and bottom surface of the channel hole 160H. A filling insulating layer 165 may fill an internal space of the channel layer 163. In an embodiment, the filling insulating layer 165 may be omitted, and in this case, the channel layer 163 may have a pillar structure without an internal space. A conductive plug 167 may be disposed on the upper side of the channel hole 160H to contact the channel layer 163 and block an entrance of the channel hole 160H.

A plurality of dummy channel structures 160D may be disposed in the connection region CON. The plurality of dummy channel structures 160D may not be electrically connected to the bit lines BL. The plurality of dummy channel structures 160D may penetrate the interlayer insulating layer CL, the stacked structure 150, the upper base layer 140, the insulating plate 133, and at least a part of the substrate layer 120 and extend in the vertical direction (Z direction). The plurality of dummy channel structures 160D may be formed in a dummy channel hole 160DH. Similar to the channel structure 160, each of the plurality of dummy channel structures 160D may include a gate insulating layer 161D, a channel layer 163D, a filling insulating layer 165D, and a conductive plug 167D. The gate insulating layer 161D, the channel layer 163D, the filling insulating layer 165D, and the conductive plug 167D of the dummy channel structures 160D may be formed of the same materials as the gate insulating layer 161, the channel layer 163, the filling insulating layer 165, and the conductive plug 167, respectively, of the channel structures 160. In an embodiment, the horizontal area and vertical length of each of the plurality of dummy channel structures 160D may be greater than the horizontal area and vertical length of each of the plurality of channel structures 160.

A first upper insulating layer UL1 and a second upper insulating layer UL2 may be sequentially disposed on the stacked structure 150 and the interlayer insulating layer CL. The first upper insulating layer UL1 and the second upper insulating layer UL2 may include silicon oxide, silicon nitride, or a combination thereof.

A plurality of bit line contacts BLC may contact the conductive plug 167 of the channel structure 160 and the conductive plug 167D of the dummy channel structure 160D through the first upper insulating layer UL1. A bit line BL may be disposed on a bit line contact BLC contacting the conductive plug 167 of the channel structure 160 among the plurality of bit line contacts BLC. The bit line BL may not be disposed on a bit line contact BLC contacting the conductive plug 167D of the dummy channel structure 160D among the plurality of bit line contacts BLC. The plurality of bit lines BL may penetrate the second upper insulating layer UL2 and contact the bit line contacts BLC respectively corresponding thereto. The plurality of bit lines BL may be connected to the channel structures 160 corresponding thereto through the plurality of bit line contacts BLC corresponding thereto.

Each of a plurality of contact structures CNT may be disposed in the connection region CON. Each of the plurality of contact structures CNT may penetrate the first upper insulating layer UL1, the interlayer insulating layer CL, and a part of the gate electrode 153 and extend in the vertical direction (Z direction). The plurality of contact structures CNT may penetrate the first upper insulating layer UL1 and connect a plurality of wiring layers ML in contact with the plurality of contact structures CNT to the plurality of gate electrodes 153.

FIG. 5A is a plan view illustrating the first key pattern region KPB of the semiconductor device 100 according to an example embodiment. FIG. 5B is a cross-sectional view taken along a line A-A′ of FIG. 5A.

Referring to FIGS. 5A and 5B, the semiconductor device 100 may include the first key pattern region KPB positioned on the scribe lane region SLR. In an embodiment, a plurality of first pattern structures 170B may be disposed in the first key pattern region KPB. In an embodiment, the horizontal area and vertical length of each of the plurality of first pattern structures 170B may be greater than the horizontal area and vertical length of each of a plurality of second pattern structures 170S, as described below with reference to FIGS. 6A and 6B. Each of the plurality of first pattern structures 170B may have a rectangular shape on a plane (X-Y plane) perpendicular to the vertical direction (Z direction). In an embodiment, the plurality of first pattern structures 170B may be arranged to form a cross shape. However, the inventive concept is not limited thereto, and the plurality of first pattern structures 170B may be arranged in other ways as desired. In an embodiment, a pattern insulating layer 115 may be disposed in a region of the first key pattern region KPB where the plurality of first pattern structures 170B are disposed. For example, as shown in FIG. 5A, the pattern insulating layer 115 may be disposed in a region of the first key pattern region KPB where the plurality of first pattern structures 170B are disposed, and the substrate layer 120 may surround the pattern insulating layer 115.

The semiconductor device 100 may include the substrate 50, the peripheral circuit wiring structure 70 disposed on the substrate 50, and the interlayer insulating layer 80 disposed on the substrate 50 and covering the peripheral circuit wiring structure 70 in the first key pattern region KPB. The substrate 50, the peripheral circuit wiring structure 70, and the interlayer insulating layer 80 of FIG. 5B may respectively correspond to the substrate 50, the peripheral circuit wiring structure 70, and the interlayer insulating layer 80 of FIG. 4.

A capping insulating layer 110 may be disposed on the interlayer insulating layer 80 in the first key pattern region KPB. The capping insulating layer 110 may include a first capping insulating layer 111 and a second capping insulating layer 113 sequentially disposed on the interlayer insulating layer 80. The second barrier metal layer VBM and the via BV may be disposed on the capping insulating layer 110 to sequentially cover the inner wall of a via hole. The capping insulating layer 110, the via BV, and the second barrier metal layer VBM of FIG. 5B may respectively correspond to the capping insulating layer 110, the via BV, and the second barrier metal layer VBM of FIG. 4.

The pattern insulating layer 115 and the first barrier metal layer BM may be disposed on the capping insulating layer 110. The substrate layer 120, the insulating plate 133, and the upper base layer 140 may be sequentially disposed on the first barrier metal layer BM. The pattern insulating layer 115 may be formed by etching the sequentially disposed first barrier metal layer BM, the substrate layer 120, the insulating plate 133, and the upper base layer 140, and filling with an insulating material layer. Accordingly, the pattern insulating layer 115 may extend through the first barrier metal layer BM in the vertical direction (Z direction). For example, the first barrier metal layer BM may be removed from a region where the pattern insulating layer 115 is disposed. In an embodiment, the upper surface of the pattern insulating layer 115 may be positioned at the same vertical level as the lower surface of the lowermost insulating layer among the plurality of insulating layers 151 (i.e., the same vertical level as the upper surface of the upper base layer 140). In an embodiment, the pattern insulating layer 115 may contact an upper surface of the second capping insulating layer 113. In an embodiment, the lower surface of the pattern insulating layer 115 may be positioned at the same vertical level as the upper surface of the second capping insulating layer 113. In another embodiment, the lower surface of the pattern insulating layer 115 may be positioned at a lower vertical level than the upper surface of the second capping insulating layer 113. For example, the pattern insulating layer 115 may extend through the second capping insulating layer 113 in the vertical direction (Z direction). In an embodiment, the pattern insulating layer 115 may be silicon oxide.

In an embodiment, the pattern insulating layer 115 may include the same material as the second capping insulating layer 113. For example, the pattern insulating layer 115 and the second capping insulating layer 113 may include silicon oxide.

The stacked structure 150 may be disposed on the pattern insulating layer 115 and the upper base layer 140. The stacked structure 150 may include the plurality of insulating layers 151 and the plurality of gate electrodes 153 alternately disposed in the vertical direction (Z direction). The stacked structure 150 of FIG. 5B may correspond to the stacked structure 150 of FIG. 4.

Each of the plurality of first pattern structures 170B may be disposed on the first key pattern region KPB of the scribe lane region SLR. In an embodiment, the plurality of first pattern structures 170B may be disposed to overlap the pattern insulating layer 115 in a vertical direction. Each of the plurality of first pattern structures 170B may penetrate the stacked structure 150 and at least a part of the pattern insulating layer 115 and extend in the vertical direction (Z direction). Side surfaces of the plurality of first pattern structures 170B may be discontinuous in the vertical direction (Z direction). For example, at a middle portion of the first pattern structures 170B, a portion of the side surface may be parallel to an upper surface of the substrate 50, and at upper and lower portions of the first pattern structures 170B, portions of the surface may be at an acute angle to the upper surface of the substrate 50.

Each of the plurality of first pattern structures 170B may include a first barrier layer 171B and a first metal layer 173B. The first barrier layer 171B and the first metal layer 173B may be sequentially disposed on the inner wall of a first pattern channel hole 170BH. The first barrier layer 171B may contact side surfaces of the plurality of insulating layers 151 and the plurality of gate electrodes 153, and the first metal layer 173B may contact the first barrier layer 171B. The first metal layer 173B may be spaced apart from the plurality of insulating layers 151 and the plurality of gate electrodes 153 by the first barrier layer 171B. For example, the first barrier layer 171B and the first metal layer 173B may be sequentially and conformally disposed on the sidewall and bottom surface of the first pattern channel hole 170BH. In an embodiment, the first barrier layer 171B may include TIN, Ti—Si—N(TSN), WN, or WSi. In an embodiment, the first barrier layer 171B may include TIN, Ti—Si—N(TSN), and a combination thereof. For example, the first barrier layer 171B may be formed of TIN, Ti—Si—N(TSN), and a combination thereof. In an embodiment, the first metal layer 173B may include tungsten, nickel, cobalt, tantalum, tungsten nitride, titanium nitride, tantalum nitride, or a combination thereof. For example, the first metal layer 173B may be formed of tungsten, nickel, cobalt, tantalum, tungsten nitride, titanium nitride, tantalum nitride, or a combination thereof.

In FIG. 5B, each of the plurality of first pattern structures 170B is illustrated as having the same length in the vertical direction (length in the Z direction), but is not limited thereto. For example, some of the plurality of first pattern structures 170B may have different lengths from the other first pattern structures 170B in the vertical direction, and all of the plurality of first pattern structures 170B may have different lengths in the vertical direction.

The first upper insulating layer UL1 and the second upper insulating layer UL2 may be sequentially disposed on the stacked structure 150. The first upper insulating layer UL1 and the second upper insulating layer UL2 of FIG. 5B may respectively correspond to the first upper insulating layer UL1 and the second upper insulating layer UL2 of FIG. 4.

FIG. 6A is a plan view illustrating the second key pattern region KPS of the semiconductor device 100 according to an embodiment. FIG. 6B is a cross-sectional view taken along a line B-B′ of FIG. 6A.

Referring to FIGS. 6A and 6B, the semiconductor device 100 may include the second key pattern region KPS positioned on the scribe lane region SLR. The plurality of second pattern structures 170S may be disposed in the second key pattern region KPS. Each of the plurality of second pattern structures 170S may have a square shape on the plane (X-Y plane) perpendicular to the vertical direction (Z direction). In an embodiment, the plurality of second pattern structures 170S may be arranged to form a cross shape. However, the inventive concept is not limited thereto, and the plurality of second pattern structures 170S may be arranged in other ways as needed.

The semiconductor device 100 may include the substrate 50, the peripheral circuit wiring structure 70 disposed on the substrate 50, and the interlayer insulating layer 80 disposed on the substrate 50 and covering the peripheral circuit wiring structure 70 in the second key pattern region KPS. The substrate 50, the peripheral circuit wiring structure 70, and the interlayer insulating layer 80 of FIG. 6B may respectively correspond to the substrate 50, the peripheral circuit wiring structure 70, and the interlayer insulating layer 80 of FIG. 4.

In the second key pattern region KPS, the capping insulating layer 110 including the first capping insulating layer 111 and the second capping insulating layer 113, the barrier metal layer BML including the first barrier metal layer BM and the second barrier metal layer VBM, the substrate layer 120, the insulating plate 133, and the upper base layer 140 may be sequentially disposed on the interlayer insulating layer 80. For example, the pattern insulating layer 115 (see FIG. 5B) may not be disposed in the second key pattern region KPS. The capping insulating layer 110 includes a via hole of which the inner wall is covered by the second barrier metal layer VBM, and the via BV may be disposed in the via hole. The capping insulating layer 110, the substrate layer 120, the insulating plate 133, the upper base layer 140, the via BV, and the second barrier metal layer VBM of FIG. 6B may respectively correspond to the capping insulating layer 110, the substrate layer 120, the insulating plate 133, the upper base layer 140, the via BV, the first barrier metal layer BM, and the second barrier metal layer VBM of FIG. 4.

The stacked structure 150 may be disposed on the upper base layer 140. The stacked structure 150 may include the plurality of insulating layers 151 and the plurality of gate electrodes 153 alternately disposed in a vertical direction (Z direction). The stacked structure 150 of FIG. 6B may correspond to the stacked structure 150 of FIG. 4.

Each of the plurality of second pattern structures 170S may be disposed on the second key pattern region KPS of the scribe lane region SLR. Each of the plurality of second pattern structures 170S may penetrate the stacked structure 150, the upper base layer 140, the insulating plate 133, and at least a part of the substrate layer 120 and extend in the vertical direction (Z direction).

Each of the plurality of second pattern structures 170S may include a second barrier layer 171S and a second metal layer 173S. The configuration of the plurality of second pattern structures 170S may be substantially the same as the configuration of the plurality of first pattern structures 170B, when viewed in cross-section.

The first upper insulating layer UL1 and the second upper insulating layer UL2 may be sequentially disposed on the stacked structure 150. The first upper insulating layer UL1 and the second upper insulating layer UL2 of FIG. 6B may respectively correspond to the first upper insulating layer UL1 and the second upper insulating layer UL2 of FIG. 4.

The semiconductor device 100 according to an embodiment may include the pattern insulating layer 115 penetrating the barrier metal layer BML and overlapping the plurality of first pattern structures 170B in a vertical direction on the first key pattern region KPB in which the plurality of first pattern structures 170B having a relatively large horizontal area and vertical length are disposed. Accordingly, the barrier metal layer BML may be removed in the region where the plurality of first pattern structures 170B are formed, which may prevent occurrence of a channel hole punching phenomenon in a process of etching the first pattern channel hole 170BH to form the plurality of first pattern structures 170B. Accordingly, contamination of semiconductor equipment that may occur due to exposure of a part of the barrier metal layer BML by the channel hole punching phenomenon may be prevented, and separation between the substrate layer 120 and the capping insulating layer 110 that may occur during a process of removing a sacrificial layer on the first pattern channel hole 170BH formed after the etching process may be prevented. Accordingly, the structural reliability of the semiconductor device 100 may be improved.

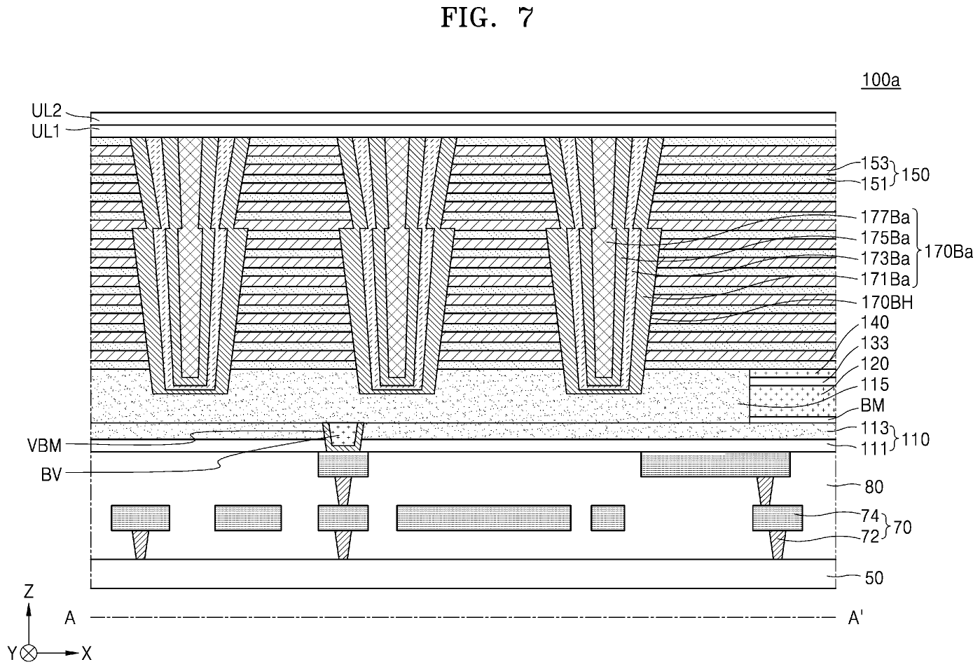

FIG. 7 is a cross-sectional view of a semiconductor device 100a according to an example embodiment. Specifically, FIG. 7 is a cross-sectional view taken along a line A-A′ of FIG. 5A. Each configuration of the semiconductor device 100a shown in FIG. 7 is similar to each configuration of the semiconductor device 100 described with reference to FIGS. 4 to 6B, and thus, hereinafter, differences therebetween are mainly described.

Referring to FIG. 7, the semiconductor device 100a may include a plurality of first pattern structures 170Ba extending through the stacked structure 150 and the pattern insulating layer 115 in a vertical direction (Z direction). Each of the plurality of first pattern structures 170Ba may include a first insulating layer 171Ba, a second insulating layer 173Ba, a third insulating layer 175Ba, and a channel layer 177Ba. The first insulating layer 171Ba, the second insulating layer 173Ba, the third insulating layer 175Ba, and the channel layer 177Ba may be sequentially disposed on the inner wall of the first pattern channel hole 170BH. In an embodiment, the first insulating layer 171Ba, the second insulating layer 173Ba, and the third insulating layer 175Ba may have an ONO structure together. For example, the first insulating layer 171Ba, the second insulating layer 173Ba, and the third insulating layer 175Ba may form an ONO structure. For example, the first insulating layer 171Ba and the third insulating layer 175Ba may include silicon oxide, and the second insulating layer 173Ba may include silicon nitride. In an embodiment, the channel layer 177Ba may include polysilicon doped with impurities and/or polysilicon undoped with impurities.

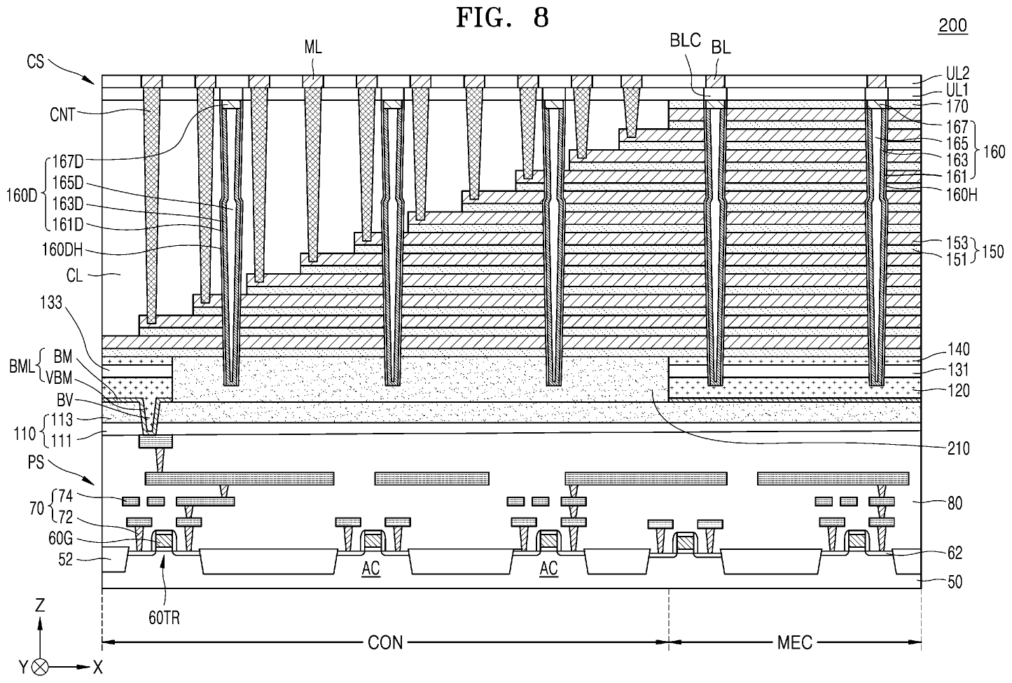

FIG. 8 is a cross-sectional view illustrating a part of the chip region (e.g., chip region CR, see FIG. 3) of a semiconductor device 200 according to an example embodiment. Each component of the semiconductor device 200 shown in FIG. 8 is similar to the corresponding component of the semiconductor device 100 described with reference to FIGS. 4 to 6B, and thus, hereinafter, differences therebetween are mainly described.

Referring to FIG. 8, the semiconductor device 200 may include a cell array structure CS and a peripheral circuit structure PS overlapping each other in a vertical direction (Z direction).

The peripheral circuit structure PS may include the substrate 50, peripheral circuit transistors 60TR disposed on the substrate 50, and the peripheral circuit wiring structure 70. The plurality of peripheral circuit transistors 60TR may include a peripheral circuit gate 60G and source/drain regions 62 disposed on parts of the substrate 50 of both sides of the peripheral circuit gate 60G. The peripheral circuit wiring structure 70 may include a plurality of peripheral circuit contacts 72 and a plurality of peripheral circuit wiring layers 74. The peripheral circuit transistor 60TR and the peripheral circuit wiring structure 70 may be covered with the interlayer insulating layer 80.

The capping insulating layer 110 may be disposed between the cell array structure CS and the peripheral circuit structure PS. The capping insulating layer 110 may include the first capping insulating layer 111 and the second capping insulating layer 113 sequentially disposed on the interlayer insulating layer 80.

The barrier metal layer BML may cover the upper surface of the capping insulating layer 110 and the inner wall of the via hole BVH penetrating the capping insulating layer 110. For example, the barrier metal layer BML may contact the upper surface of the capping insulating layer 110 and the inner wall of the via hole BVH. The barrier metal layer BML may include the first barrier metal layer BM covering the upper surface of the capping insulating layer 110 and the second barrier metal layer VBM covering the inner wall of the via hole BVH.

A substrate layer 120 may be disposed on the barrier metal layer BML. The substrate layer 120 may contact an upper surface of the barrier metal layer BML. The substrate layer 120 may fill an empty space inside the second barrier metal layer VBM covering the inner wall of the via hole BVH. The via BV may be formed together with the substrate layer 120. For example, the via BV may be formed at the same time and of the same material as the substrate layer 120.

The lower base layer 131 may be disposed on the substrate layer 120 in the memory cell region MEC, and the insulating plate 133 may be disposed on the substrate layer 120 in the connection region CON. For example, the lower base layer 131 may contact the substrate layer 120 in the memory cell region MEC, and the insulating plate 133 may contact the substrate layer 120 in the connection region CON. An upper base layer 140 may be disposed on the lower base layer 131 and the insulating plate 133. The upper base layer 140 may contact the lower base layer 131 and the insulating plate 133.

In an embodiment, a pattern insulating layer 210 may be disposed on the capping insulating layer 110 in at least a part of the connection region CON. The pattern insulating layer 210 may extend through the first barrier metal layer BM in a vertical direction (Z direction). Accordingly, the first barrier metal layer BM may be removed in the region where the pattern insulating layer 210 is disposed. In an embodiment, the upper surface of the pattern insulating layer 210 may be positioned at the same vertical level as the lower surface of the lowermost insulating layer among the plurality of insulating layers 151 (i.e., the same vertical level as the upper surface of the upper base layer 140). In an embodiment, the lower surface of the pattern insulating layer 210 may be positioned at the same vertical level as the upper surface of the second capping insulating layer 113. For example, the lower surface of the pattern insulating layer 210 may contact the upper surface of the second capping insulating layer 113. In another embodiment, the lower surface of the pattern insulating layer 210 may be positioned at a lower vertical level than the upper surface of the second capping insulating layer 113.

In an embodiment, the pattern insulating layer 210 may be formed of the same material as the second capping insulating layer 113. For example, the pattern insulating layer 210 and the second capping insulating layer 113 may be formed of silicon oxide.

In an embodiment, the pattern insulating layer 210 may not be disposed in the memory cell region MEC. Accordingly, the first barrier metal layer BM may not be removed from the memory cell region MEC.

The stacked structure 150 may be disposed on the pattern insulating layer 210 and the upper base layer 140. The stacked structure 150 may include the plurality of insulating layers 151 and the plurality of gate electrodes 153 alternately disposed in the vertical direction (Z direction). The stacked structure 150 may be covered by an interlayer insulating layer CL.

The plurality of channel structures 160 may be disposed in the memory cell region MEC. Each of the plurality of channel structures 160 may penetrate the stacked structure 150, the upper base layer 140, the lower base layer 131, and at least a part of the substrate layer 120 and extend in the vertical direction (Z direction). Each of the plurality of channel structures 160 may be provided in a channel hole 160H, and may include a gate insulating layer 161, a channel layer 163, a filling insulating layer 165, and a conductive plug 167.

The plurality of dummy channel structures 160D may be disposed in the connection region CON. The plurality of dummy channel structures 160D may not be electrically connected to the bit lines BL. Each of the plurality of dummy channel structures 160D may extend through the interlayer insulating layer CL, the stacked structure 150, and at least a part of the pattern insulating layer 210 in the vertical direction (Z direction). Lower surfaces of the plurality of dummy channel structures 160D may be at a lower vertical level than an upper surface of the pattern insulating layer 210. The pattern insulating layer 210 may contact a bottom surface and a portion of the sidewalls of the plurality of dummy channel structures 160D. Similar to the channel structure 160, each of the plurality of dummy channel structures 160D may include a gate insulating layer 161D, a channel layer 163D, a filling insulating layer 165D, and a conductive plug 167D. The gate insulating layer 161D, the channel layer 163D, the filling insulating layer 165D, and the conductive plug 167D of the dummy channel structures 160D may be formed of the same materials as the gate insulating layer 161, the channel layer 163, the filling insulating layer 165, and the conductive plug 167, respectively, of the channel structures 160. In an embodiment, the horizontal area and horizontal width of each of the plurality of dummy channel structures 160D may be greater than the horizontal area and horizontal width of each of the plurality of channel structures 160.

The first upper insulating layer UL1 and the second upper insulating layer UL2 may be sequentially disposed on the stacked structure 150 and the interlayer insulating layer CL. The plurality of bit line contacts BLC may contact the conductive plug 167 of the channel structure 160 and the conductive plug 167D of the dummy channel structure 160D through the first upper insulating layer UL1. The bit line BL may be disposed on a bit line contact BLC contacting the conductive plug 167 of the channel structure 160 among the plurality of bit line contacts BLC. The bit line BL may not be disposed on a bit line contact BLC contacting the conductive plug 167D of the dummy channel structure 160D among the plurality of bit line contacts BLC. The plurality of bit lines BL may penetrate the second upper insulating layer UL2 and contact the bit line contacts BLC corresponding thereto.

Each of the plurality of contact structures CNT may be disposed in the connection region CON. Each of the plurality of contact structures CNT may penetrate the first upper insulating layer UL1, the interlayer insulating layer CL, and a part of the gate electrode 153 and extend in the vertical direction (Z direction).

The semiconductor device 200 according to an example embodiment may include a pattern insulating layer 210 penetrating the barrier metal layer BML and overlapping the plurality of dummy channel structures 160D in a vertical direction in at least a part of the connection region CON where the dummy channel structure 160D having a relatively large horizontal area and a relatively large length is disposed. Accordingly, the barrier metal layer BML may be removed in the region where the plurality of dummy channel structures 160D are formed, which may prevent occurrence of a channel hole punching phenomenon in a process of etching the dummy channel holes 160DH to form the plurality of dummy channel structures 160D. Accordingly, contamination of semiconductor equipment that may occur due to exposure of a part of the barrier metal layer BML by the channel hole punching phenomenon may be prevented, and separation between the substrate layer 120 and the capping insulating layer 110 that may occur during a process of removing a sacrificial layer on the dummy channel holes 160DH formed after the etching process may be prevented. Accordingly, the structural reliability of the semiconductor device 200 may be improved.

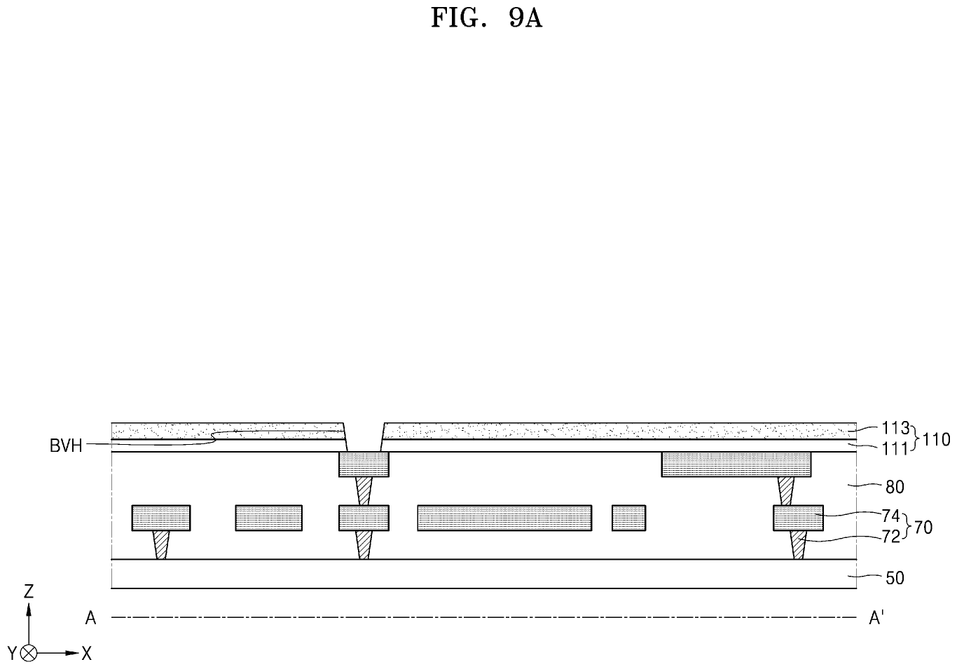

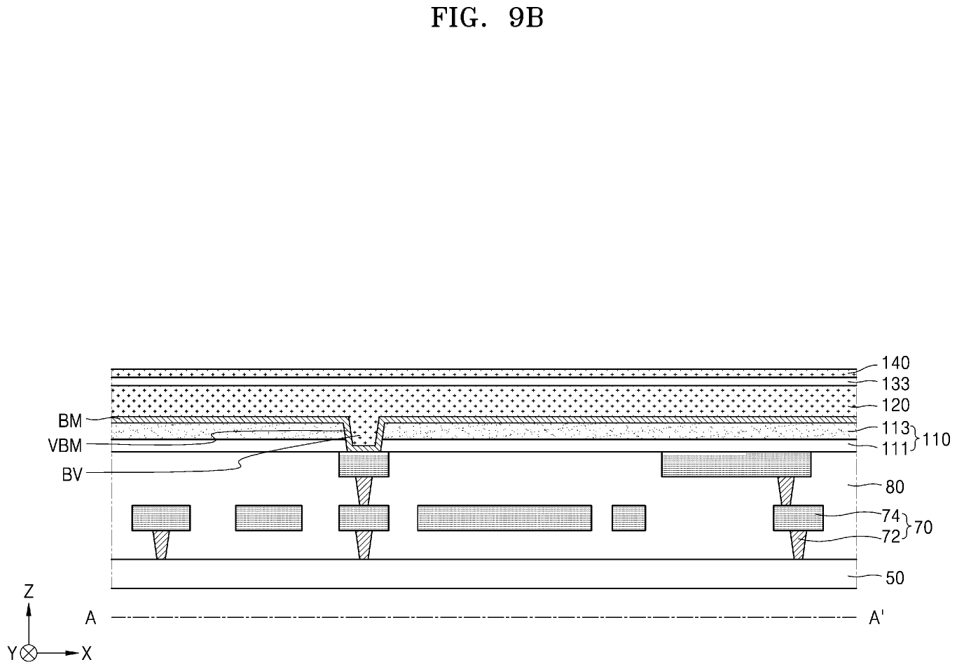

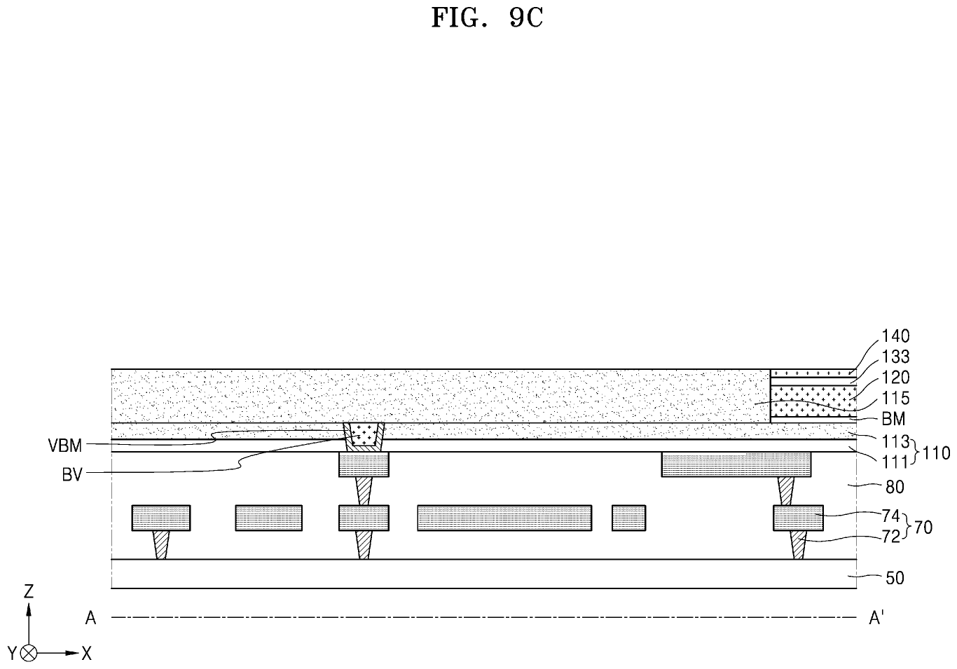

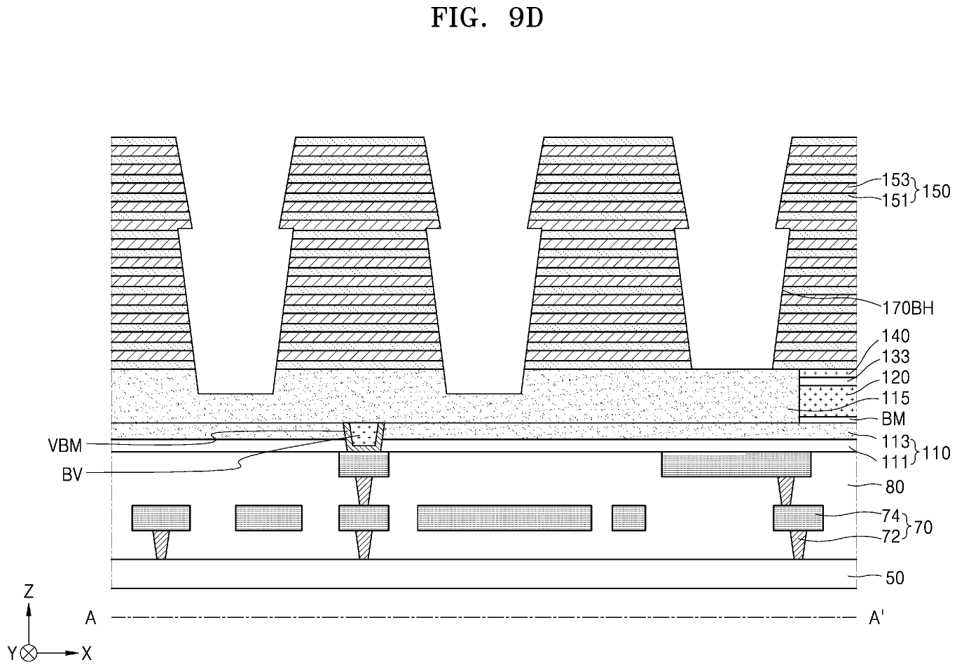

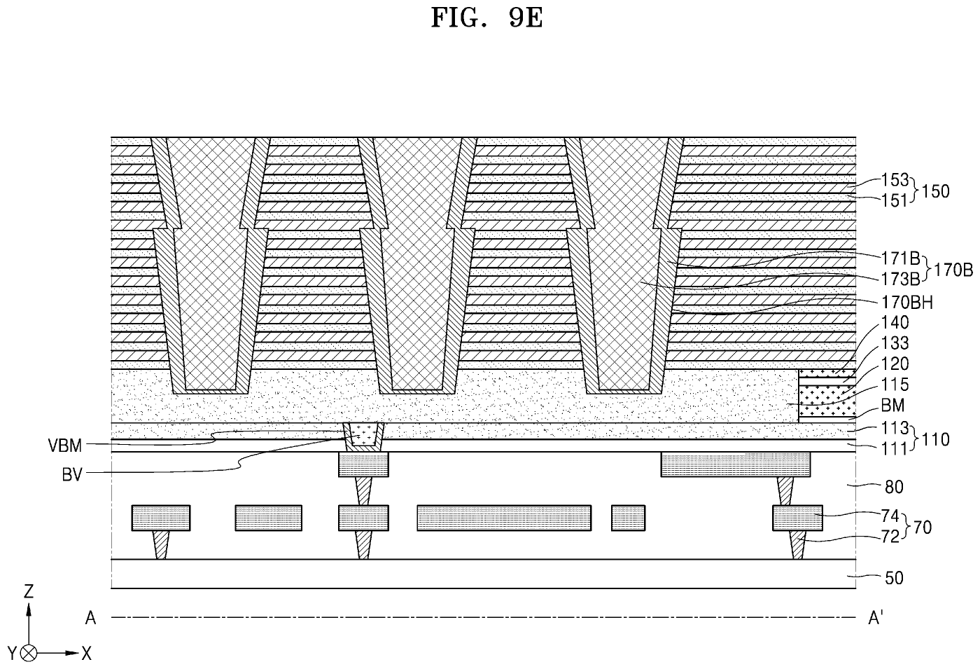

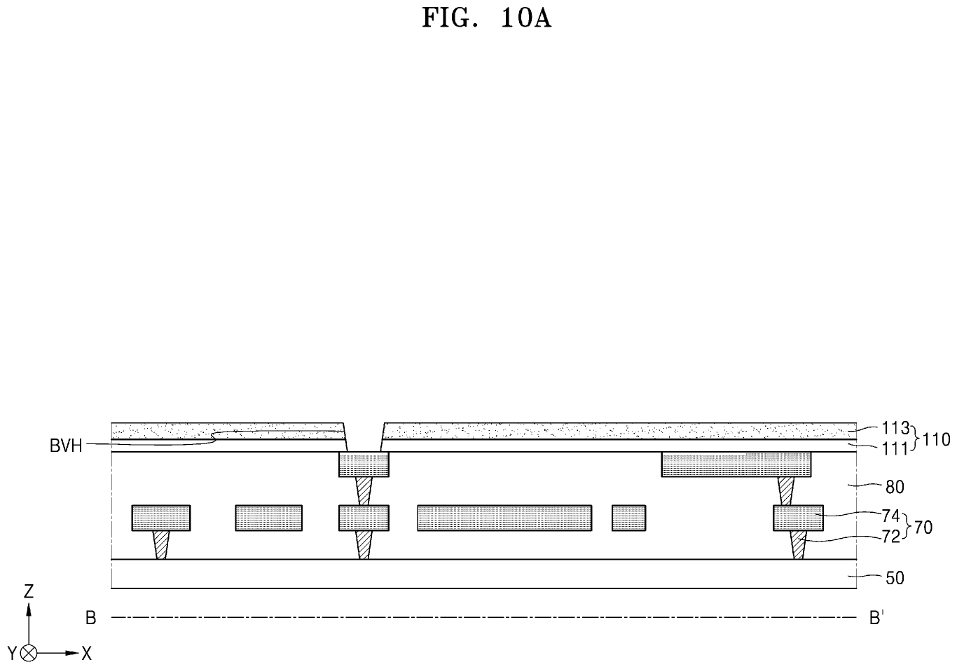

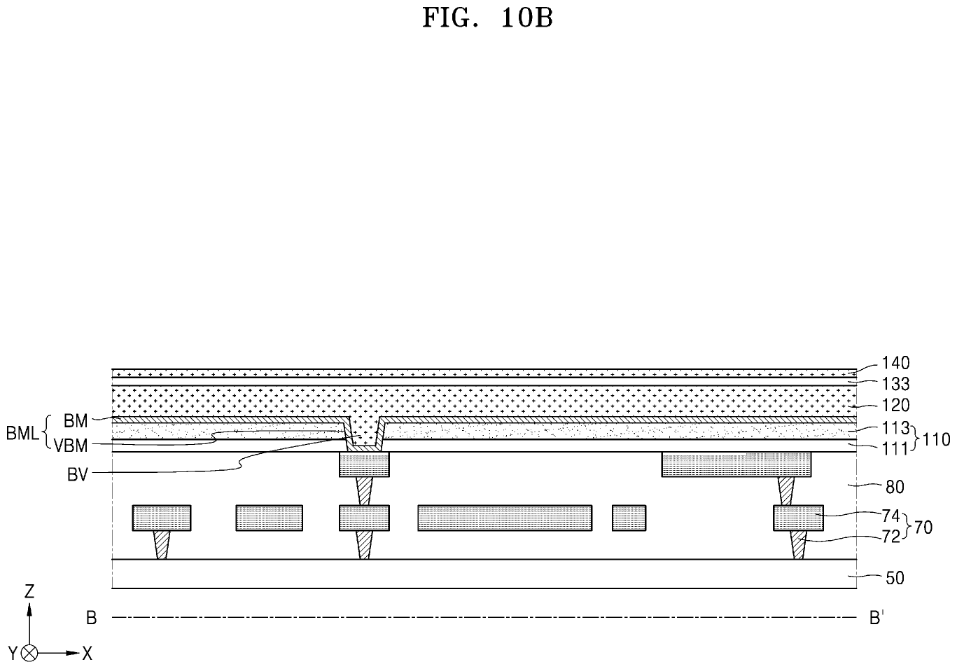

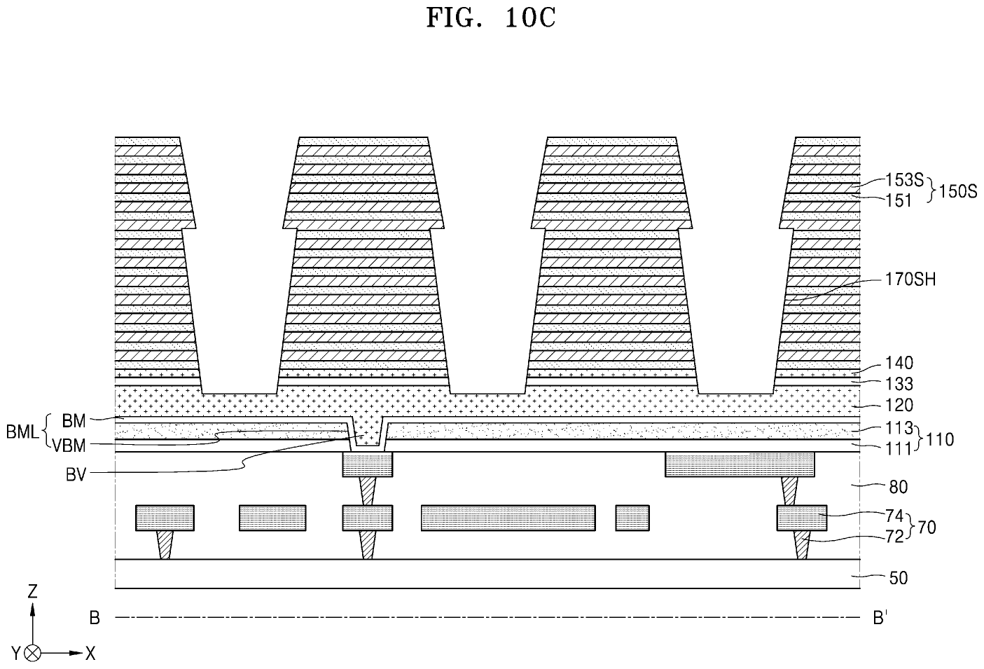

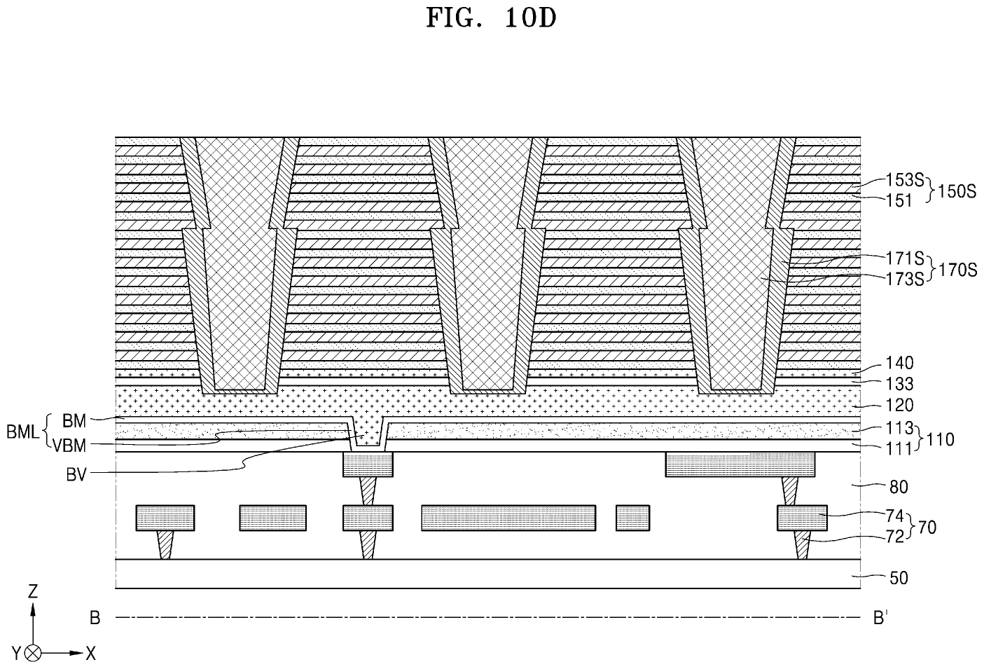

FIGS. 9A to 10D are cross-sectional views illustrating a method of manufacturing the semiconductor device 100, according to an example embodiment. Specifically, FIGS. 9A to 9E are cross-sectional views showing regions corresponding to the first key pattern region KPB, and FIGS. 10A to 10D are cross-sectional views showing regions corresponding to the second key pattern region KPS.

Referring to FIGS. 9A and 10A, the peripheral circuit structure PS including the peripheral circuit transistor 60TR disposed on the substrate 50 and the peripheral circuit wiring structure 70 covered by the interlayer insulating layer 80 may be formed. Next, the first capping insulating layer 111 and the second capping insulating layer 113 may be sequentially formed on the peripheral circuit structure PS. Next, the via hole BVH penetrating the first capping insulating layer 111 and the second capping insulating layer 113 and exposing the peripheral circuit wiring structure 70 in the bottom surface thereof may be formed.

Referring to FIGS. 9B and 10B, in a resultant of FIGS. 9A and 10A, the barrier metal layer BML covering the inner wall of the via hole BVH and the upper surface of the second capping insulating layer 113 may be formed. Next, the substrate layer 120, the insulating plate 133, and the upper base layer 140 may be sequentially formed on the barrier metal layer BML. In an embodiment, in a process of forming the substrate layer 120 on the barrier metal layer BML, the via BV filling the via hole BVH penetrating the capping insulating layer 110 may be formed together with the substrate layer 120.

Referring to FIG. 9C, in a resultant of FIGS. 9B and 10B, the substrate layer 120, the insulating plate 133, and the upper base layer 140 formed on the first key pattern region (e.g., first key pattern region KPB, see FIG. 3) may be etched. Next, the pattern insulating layer 115 may be formed on the capping insulating layer 110 of the first key pattern region (e.g., first key pattern region KPB, see FIG. 3) exposed by the etching. In this regard, the substrate layer 120, the insulating plate 133, and the upper base layer 140 formed on the second key pattern region KPS are not etched, and thus, the substrate layer 120, the insulating plate 133, and the upper base layer 140 of the second key pattern region KPS may not be removed as shown in FIG. 10B.

Referring to FIGS. 9D and 10C, a stacked structure 150S may be formed in a resultant of FIGS. 9C and 10B. Specifically, the stacked structure 150S may be formed on the pattern insulating layer 115 and the upper base layer 140 in the first key pattern region KPB, and the stacked structure 150S may be formed on the upper base layer 140 in the second key pattern region KPS. The stacked structure 150S may be formed by alternately forming a plurality of insulating layers 151 and a plurality of sacrificial layers 153S. The plurality of sacrificial layers 153S may be replaced with the plurality of gate electrodes 153 through a series of processes after the method of manufacturing the semiconductor device 100 described with reference to FIGS. 9A to 10D.

Next, the first pattern channel hole 170BH penetrating the stacked structure 150S and at least a part of the pattern insulating layer 115 may be formed in the first key pattern region KPB, and the second pattern hole 170SH penetrating the stacked structure 150S, the upper base layer 140, the insulating plate 133, and at least a part of the substrate layer 120 may be formed in the second key pattern region KPS. In an embodiment, the horizontal area and vertical length of the first pattern channel hole 170BH may be greater than the horizontal area and vertical length of the second pattern hole 170SH.

Referring to FIGS. 9E and 10D, in resultants of FIGS. 9D and 10C, the first pattern structure 170B and the second pattern structure 170S may be formed. Specifically, the first barrier layer 171B and the first metal layer 173B may be sequentially formed on the inner wall of the first pattern channel hole 170BH in the first key pattern region KPB, and the second barrier layer 171S and the second metal layer 173S may be sequentially formed on the inner wall of the second pattern hole 170SH in the second key pattern region KPS. Thereafter, the semiconductor device 100 may be formed by forming the channel structure 160, the dummy channel structure 160D, the contact structure CNT, and the bit line BL shown in FIG. 4.

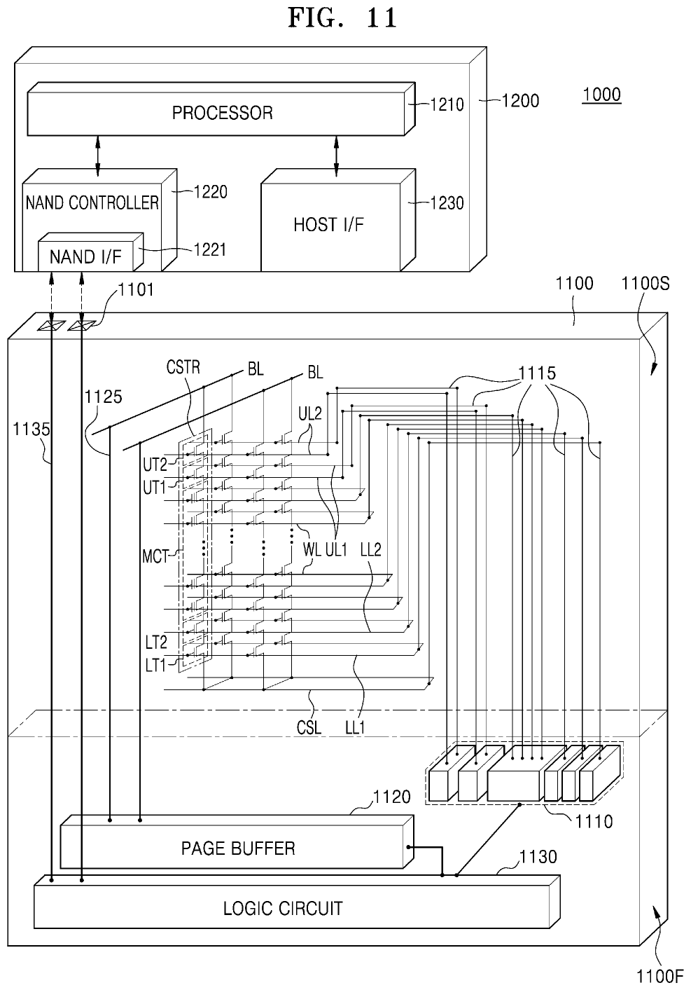

FIG. 11 is a diagram schematically illustrating an electronic system 1000 including a semiconductor device 1100 according to an example embodiment.

Referring to FIG. 11, the electronic system 1000 according to an example embodiment may include the semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid state drive device (SSD) including at least one semiconductor device 1100, a universal serial bus (USB), a computing system, a medical device, or a communication device.

The semiconductor device 1100 may be a non-volatile memory device. For example, the semiconductor device 1100 may be a NAND flash memory device including at least one of the structures described above with respect to the semiconductor devices 100, 100a, and 200 with reference to FIGS. 3 to 8. The semiconductor device 1100 may include a first structure 1100F and a second structure 1100S on the first structure 1100F. In some embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including the bit line BL, the common source line CSL, the plurality of word lines WL, the first and second gate upper lines UL1 and UL2, the first and second gate lower lines LL1 and LL2, and a plurality of memory cell strings CSTR between the bit line BL and the common source line CSL.

In the second structure 1100S, the plurality of memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously modified according to some embodiments.

In some embodiments, the upper transistors UT1 and UT2 may include string selection transistors, and the lower transistors LT1 and LT2 may include ground selection transistors. The plurality of gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2.

The common source line CSL, the plurality of gate lower lines LL1 and LL2, the plurality of word lines WL, and the plurality of gate upper lines UL1 and UL2 may be electrically connected to the decoder circuit 1110 through a plurality of first connection wirings 1115 extending to the second structure 1100S in the first structure 1100F. The plurality of bit lines BL may be electrically connected to the page buffer 1120 through a plurality of second connection wirings 1125 extending to the second structure 1100S in the first structure 1100F.

In the first structure 1100F, the decoder circuit 1110 and the page buffer 1120 may perform a control operation on at least one of the plurality of memory cell transistors MCT. The decoder circuit 1110 and the page buffer 1120 may be controlled by the logic circuit 1130.

The semiconductor device 1100 may communicate with the controller 1200 through the input/output pads 1101 electrically connected to the logic circuit 1130. The input/output pads 1101 may be electrically connected to the logic circuit 1130 through input/output connection wiring 1135 extending to the second structure 1100S in the first structure 1100F.

The controller 1200 may include a processor 1210, a NAND controller 1220, and a host interface 1230. According to some embodiments, the electronic system 1000 may include a plurality of semiconductor devices 1100, and, in this case, the controller 1200 may control the plurality of semiconductor devices 1100.

The processor 1210 may control the overall operation of the electronic system 1000 including the controller 1200. The processor 1210 may operate according to certain firmware and may access the semiconductor device 1100 by controlling the NAND controller 1220. The NAND controller 1220 may include a NAND interface 1221 that processes communication with the semiconductor device 1100. A control command for controlling the semiconductor device 1100, data to be written to the plurality of memory cell transistors MCT of the semiconductor device 1100, and data to be read from the plurality of memory cell transistors MCT of the semiconductor device 1100 may be transmitted through the NAND interface 1221. The host interface 1230 may provide a communication function between the electronic system 1000 and an external host. When a control command is received from an external host through the host interface 1230, the processor 1210 may control the semiconductor device 1100 in response to the control command.

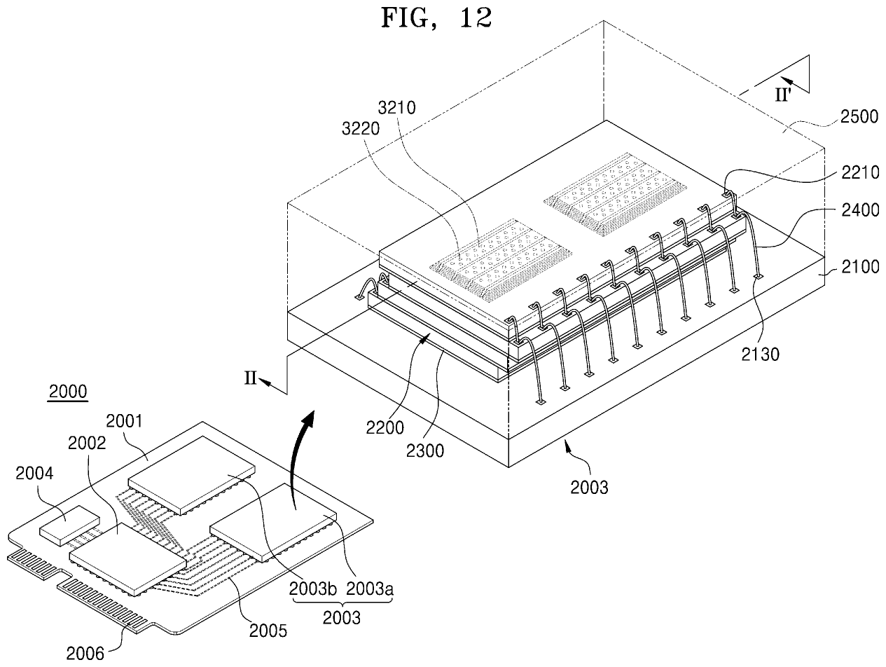

FIG. 12 is a schematic perspective view of an electronic system 2000 including a semiconductor device according to an example embodiment.

Referring to FIG. 12, the electronic system 2000 according to an example embodiment may include a main substrate 2001, a controller 2002 mounted on the main substrate 2001, one or more semiconductor packages 2003, and DRAM 2004. The semiconductor package 2003 and the DRAM 2004 may be connected to the controller 2002 through a plurality of wiring patterns 2005 formed on the main substrate 2001.

The main substrate 2001 may include a connector 2006 including a plurality of pins coupled to an external host. The number and arrangement of the plurality of pins in the connector 2006 may vary depending on a communication interface between the electronic system 2000 and the external host. In some embodiments, the electronic system 2000 may communicate with an external host according to any one of interfaces, such as Universal Serial Bus (USB), Peripheral Component Interconnect Express (PCI-Express), Serial Advanced Technology Attachment (SATA), M-Phy for Universal Flash Storage (UFS), etc. In some embodiments, the electronic system 2000 may operate by power supplied from an external host through the connector 2006. The electronic system 2000 may further include a Power Management Integrated Circuit (PMIC) that distributes the power supplied from the external host to the controller 2002 and the semiconductor package 2003.

The controller 2002 may write data to the semiconductor package 2003 or read data from the semiconductor package 2003 and improve the operating speed of the electronic system 2000.

The DRAM 2004 may be a buffer memory mitigating a speed difference between the semiconductor package 2003, which is a data storage space, and an external host. The DRAM 2004 included in the electronic system 2000 may also operate as a kind of cache memory, and may provide a space temporarily storing data in a control operation on the semiconductor package 2003. When the electronic system 2000 includes the DRAM 2004, the controller 2002 may further include a DRAM controller controlling the DRAM 2004 in addition to the NAND controller controlling the semiconductor package 2003.

The semiconductor package 2003 may include first and second semiconductor packages 2003a and 2003b spaced apart from each other. Each of the first and second semiconductor packages 2003a and 2003b may be a semiconductor package including the plurality of semiconductor chips 2200. Each of the first and second semiconductor packages 2003a and 2003b may include a package substrate 2100, a plurality of semiconductor chips 2200 on the package substrate 2100, an adhesive layer 2300 disposed on a lower surface of each of the plurality of semiconductor chips 2200, a connection structure 2400 electrically connecting the plurality of semiconductor chips 2200 and the package substrate 2100, and a molding layer 2500 covering the plurality of semiconductor chips 2200 and the connection structure 2400 on the package substrate 2100.

The package substrate 2100 may be a printed circuit board including a plurality of package upper pads 2130. Each of the plurality of semiconductor chips 2200 may include input/output pads 2210. The input/output pads 2210 may correspond to the input/output pads 1101 of FIG. 11. Each of the plurality of semiconductor chips 2200 may include a plurality of gate stacks 3210 and a plurality of channel structures 3220. Each of the plurality of semiconductor chips 2200 may include at least one of the structures described above with respect to the semiconductor devices 100, 100a, and 200 with reference to FIGS. 3 to 8.

In some embodiments, the connection structure 2400 may be a bonding wire electrically connecting the input/output pad 2210 and the package upper pad 2130. Accordingly, in the first and second semiconductor packages 2003a and 2003b, the plurality of semiconductor chips 2200 may be electrically connected to each other using a bonding wire method, and may be electrically connected to the package upper pads 2130 of the package substrate 2100. In some embodiments, in the first and second semiconductor packages 2003a and 2003b, the plurality of semiconductor chips 2200 may be electrically connected to each other by a connection structure including a through silicon via TSV instead of the connection structure 2400 of the bonding wire method.

In some embodiments, the controller 2002 and the plurality of semiconductor chips 2200 may be included in one package. In some embodiments, the controller 2002 and the plurality of semiconductor chips 2200 may be mounted on a separate interposer substrate different from the main substrate 2001, and the controller 2002 and the plurality of semiconductor chips 2200 may be connected to each other by wirings formed on the interposer substrate.

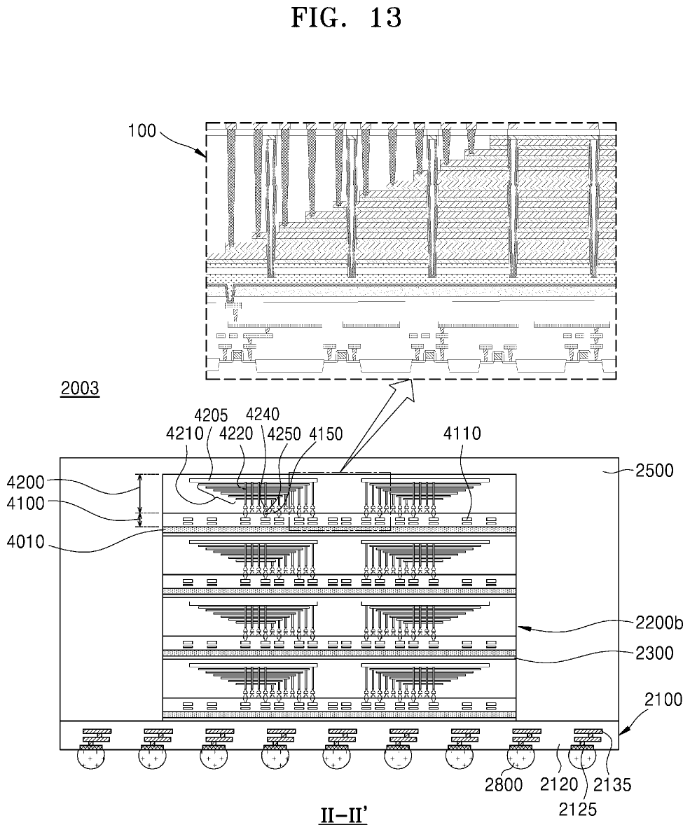

FIG. 13 is a schematic cross-sectional view of semiconductor packages according to an example embodiment. In FIG. 13, the configuration along the line II-II′ of FIG. 12 is shown in more detail.

Referring to FIG. 13, in a semiconductor package 2003, each of semiconductor chips 2200b may include a semiconductor substrate 4010, a first structure 4100 on the semiconductor substrate 4010, and a second structure 4200 bonded to the first structure 4100 using a wafer bonding method on the first structure 4100.

The first structure 4100 may include a peripheral circuit region including a peripheral wiring 4110 and first bonding structures 4150. The second structure 4200 may include a common source line 4205, a gate stack structure 4210 between the common source line 4205 and the first structure 4100, memory channel structures 4220 penetrating the gate stack structure 4210, and second bonding structures 4250 electrically connected to the word lines (e.g., word lines WL of FIG. 11) of the memory channel structures 4220 and the gate stack structure 4210, respectively. For example, the second bonding structures 4250 may be electrically connected to the memory channel structures 4220 and the word lines (e.g., word lines WL of FIG. 11) respectively through the bit lines 4240 electrically connected to the memory channel structures 4220 and gate connection wirings electrically connected to word lines (e.g., word lines WL in FIG. 11). The first bonding structures 4150 of the first structure 4100 and the second bonding structures 4250 of the second structure 4200 may be bonded in contact with each other. Bonded parts of the first bonding structures 4150 and the second bonding structures 4250 may include, for example, copper (Cu).

Each of the semiconductor chips 2200b may further include the input/output pads (e.g., input/output pads 2210 in FIG. 12) electrically connected to the peripheral wirings 4110 of the first structure 4100.

The semiconductor chips 2200 of FIG. 12 and the semiconductor chips 2200b of FIG. 13 may be electrically connected to each other by the connection structures 2400 in the form of bonding wires. However, in some embodiments, semiconductor chips in one semiconductor package, such as the semiconductor chips 2200 of FIG. 12 and the semiconductor chips 2200b of FIG. 13, may be electrically connected to each other by a connection structure including the through electrode TSV.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate comprising a chip region and a scribe lane region around the chip region and comprising a first key pattern region;
a capping insulating layer disposed on the scribe lane region;
a barrier metal layer covering the capping insulating layer and an inner wall of a via hole penetrating the capping insulating layer;
a substrate layer disposed on the barrier metal layer and filling the via hole;
an insulating plate and an upper base layer sequentially disposed on the substrate layer;
a pattern insulating layer disposed on the capping insulating layer in the first key pattern region;
a stacked structure disposed on the upper base layer and the pattern insulating layer; and
a plurality of first pattern structures overlapping the pattern insulating layer in a vertical direction and penetrating the stacked structure and a part of the pattern insulating layer,
wherein the pattern insulating layer extends through the barrier metal layer in the first key pattern region in a vertical direction.

2. The semiconductor device of claim 1, wherein an upper surface of the pattern insulating layer is positioned at a same vertical level as an upper surface of the upper base layer.

3. The semiconductor device of claim 1, wherein a lower surface of the pattern insulating layer is positioned at a same vertical level as an upper surface of the capping insulating layer.

4. The semiconductor device of claim 1, wherein the scribe lane region further includes a second key pattern region, and a plurality of second pattern structures are disposed in the second key pattern region.

5. The semiconductor device of claim 4, wherein the pattern insulating layer is not disposed in the second key pattern region.

6. The semiconductor device of claim 4, wherein a horizontal area and a vertical length of each of the plurality of first pattern structures are greater than a horizontal area and a vertical length of each of the plurality of second pattern structures.

7. The semiconductor device of claim 1, wherein each of the first pattern structures includes a first barrier layer and a first metal layer sequentially disposed on an inner wall of a first pattern channel hole positioned in the stacked structure and the pattern insulating layer.

8. The semiconductor device of claim 7, wherein the first barrier layer includes any one of TiN, TSN, and a combination thereof, and the first metal layer includes any one of tungsten, nickel, cobalt, tantalum, tungsten nitride, titanium nitride, tantalum nitride, or a combination thereof.

9. The semiconductor device of claim 1, wherein each of the first pattern structures includes a plurality of insulating layers and a channel layer sequentially formed on an inner wall of a first pattern channel hole positioned in the stacked structure and the pattern insulating layer.

10. The semiconductor device of claim 9, wherein the plurality of insulating layers form an oxide-nitride-oxide (ONO) structure.

11. A semiconductor device comprising:
a substrate comprising a chip region comprising a memory cell region and a connection region;
a capping insulating layer disposed on the chip region;
a barrier metal layer covering the capping insulating layer and an inner wall of a via hole penetrating the capping insulating layer;
a substrate layer disposed on the barrier metal layer and filling the via hole;
a lower base layer disposed on the substrate layer in the memory cell region and an insulating plate disposed on the substrate layer in the connection region;
an upper base layer disposed on the lower base layer and the insulating plate;
a pattern insulating layer disposed on the capping insulating layer in a partial region of the connection region;
a stacked structure disposed on the pattern insulating layer and the upper base layer; and
a plurality of dummy channel structures overlapping the pattern insulating layer in a vertical direction and penetrating the stacked structure and a part of the pattern insulating layer,
wherein the pattern insulating layer extends through the barrier metal layer in the connection region in a vertical direction.

12. The semiconductor device of claim 11, wherein an upper surface of the pattern insulating layer is positioned at a same vertical level as an upper surface of the upper base layer.

13. The semiconductor device of claim 11, wherein a lower surface of the pattern insulating layer is positioned at a same vertical level as an upper surface of the capping insulating layer.

14. The semiconductor device of claim 11, further comprising:
a plurality of channel structures disposed on the memory cell region,
wherein a horizontal area and a vertical length of each of the plurality of dummy channel structures are greater than a horizontal area and a vertical length of each of the plurality of channel structures.

15. The semiconductor device of claim 11, wherein the capping insulating layer includes a first capping insulating layer and a second capping insulating layer disposed on the first capping insulating layer, and the second capping insulating layer and the pattern insulating layer include a same material.

16. The semiconductor device of claim 15, wherein the second capping insulating layer and the pattern insulating layer include silicon oxide.

17. The semiconductor device of claim 11, wherein a pattern insulating layer is not disposed in the memory cell region.

18. An electronic system comprising:
a main substrate;
a semiconductor device on the main substrate; and
a controller electrically connected to the semiconductor device on the main substrate;
wherein the semiconductor device includes:
a substrate comprising a chip region and a scribe lane region around the chip region and comprising a first key pattern region;
a capping insulating layer disposed on the scribe lane region;
a barrier metal layer covering the capping insulating layer and an inner wall of a via hole penetrating the capping insulating layer;
a substrate layer disposed on the barrier metal layer and filling the via hole;
an insulating plate and an upper base layer sequentially disposed on the substrate layer;
a pattern insulating layer disposed on the capping insulating layer in the first key pattern region;
a stacked structure disposed on the upper base layer and the pattern insulating layer; and
a plurality of first pattern structures overlapping the pattern insulating layer in a vertical direction and penetrating the stacked structure and a part of the pattern insulating layer,
wherein the pattern insulating layer extends through the barrier metal layer in the first key pattern region in a vertical direction.

19. The electronic system of claim 18, wherein a lower surface of the pattern insulating layer is positioned at a same vertical level as an upper surface of the capping insulating layer.

20. The electronic system of claim 19,
wherein the chip region of the substrate includes a memory cell region and a connection region, and the semiconductor device further includes a second pattern insulating layer disposed on the capping insulating layer in the connection region; and a plurality of dummy channel structures overlapping the second pattern insulating layer in a vertical direction and penetrating a part of the second pattern insulating layer and the stacked structure, and
wherein the second pattern insulating layer extends through the barrier metal layer in the connection region in a vertical direction.
